(19) United States
(12) Patent Application Publication
(10) Pub. No.: US 2011/0247865 A1
(43) Pub. Date: Oct. 13, 2011

(54) METHOD FOR PRODUCING MULTILAYER WIRING SUBSTRATE AND MULTILAYER WIRING SUBSTRATE

(75) Inventor: Mitsuyuki TSURUMI, Kanagawa (JP)

(73) Assignee: FUJIFILM CORPORATION, Tokyo (JP)

(21) Appl. No.: 13/167,743

(22) Filed: Jun. 24, 2011

Related U.S. Application Data
(63) Continuation of application No. PCT/JP2009/068576, filed on Oct. 29, 2009.

(30) Foreign Application Priority Data
Dec. 26, 2008 (JP) 2008-334602

(51) Int. Cl. H05K 1/03; H05K 3/10; B05D 1/38; B05D 5/12; B05D 3/00

(52) U.S. Cl. 174/255; 427/97.5; 205/122

(57) ABSTRACT

The present invention provides a method for producing a multilayer wiring substrate, including: forming a laminated body having an insulating resin layer and a polymer adhesive layer, on a surface of a first wiring substrate wherein the polymer adhesive layer contains a polymer precursor interacting with a plating catalyst or a precursor thereof, and a reactive group bonding with an adjacent layer on the first wiring substrate side; applying energy to a region outside of a via connection portion on the surface of the laminated body, to form a patterned polymer adhesive layer; applying a plating catalyst or a precursor thereof to the patterned polymer adhesive layer, and carrying out a first electroless plating, to form a second metal wiring on the surface of the patterned polymer adhesive layer; and forming a via by utilizing the patterned second metal wiring as a mask, and subsequently carrying out a desmear treatment.

### CROSS-REFERENCE TO RELATED APPLICATIONS

This application is a continuation-in-part application of PCT application Ser. No. PCT/JP2009/068576, filed Oct. 29, 2009, which is based upon and claims the benefit of priority from prior Japanese Patent Application No. 2008-334602, filed Dec. 26, 2008. The entire contents of these applications are incorporated herein by reference in their entirety.

### BACKGROUND OF THE INVENTION

1. Field of the invention

The present invention relates to a method for producing a multilayer wiring substrate and a multilayer wiring substrate.

2. Description of the Related Art

Conventionally, a metal wiring substrate having wiring made of a metal pattern formed on a surface of an insulating substrate has been widely used for electronic components or semiconductor devices.

Such a metal pattern material is produced mainly by a subtractive method. The subtractive method includes: forming a photosensitive layer that is sensitive to radiation of actinic rays on a metal film that has been formed on a substrate; exposing the photosensitive layer to light in an image-wise manner; developing the same to form a resist image; etching the metal film to form a metal pattern; and then removing the resist.

In the metal pattern obtained by the above method, the metal film is adhered to the substrate by an anchoring effect that occurs due to irregularities formed on the substrate surface. Therefore, owing to the irregularities of a substrate interface portion between the substrate and the obtained metal pattern, the wiring edge portion becomes rough, and there has been a problem in that the width of wiring lines cannot be made constant so that a wiring form according to designed values is less likely to obtain, or a portion that is connected to the adjacent wiring line may be produced or breaking of wiring lines may occur at the formation of a fine wiring. Further, since the substrate surface needs to be treated with a strong acid such as chromium acid to be roughened, it is necessary to perform a complicated process in order to obtain a metal pattern having excellent adhesiveness between a metal film and a substrate.

Moreover, as demands for more sophisticated electronic apparatuses increase, large scale integration or high density packaging of the electronic devices has advanced, and miniaturization or density growth of a printed wiring board used for these devices has also progressed.

Among these techniques, in order to form a metal layer that exhibits excellent adhesion to a smooth substrate surface, a method using a polymer compound capable of forming an interaction with a plating catalyst has been proposed (see, for example, Japanese Patent Application Laid-Open (JP-A) No. 2006-60149). According to this method, by forming a pattern using a polymer compound having excellent affinity with a metal, a metal film that exhibits excellent adhesion also to a smooth substrate can be formed. It is possible to make vias in such a laminated body to realize three-dimensional connection. However, this technology is based on the assumption that the polymer adhesive layer is formed in a patterned manner, and is not based on the assumption that the wiring is formed in accordance with a general semiadditive method.

In accordance with the semiadditive method, a technique of patterning a copper foil from the top of a copper clad laminate through the use of a resist pattern to form a copper foil pattern, and then forming a via using the pattern as a conformal mask has been proposed (see, for example, JP-A No. 2008-198922). In this method, since a resist is used for forming the conformal mask, processes for forming the resist, exposure, and peeling the resist are needed before the formation of vias, resulting in requiring complicated processes.

Therefore, in regard to the production of a fine multilayer wiring substrate, a means for forming a multilayer wiring capable of forming an accurate multilayer wiring by a simple process has been required.

### SUMMARY OF THE INVENTION

The present invention has been made in view of the above-described disadvantages of the conventional technologies, and aims to accomplish the following.

Namely, an object of the invention is to provide a method for producing a multilayer wiring substrate, which is suitable for forming a fine wiring in accordance with a semiadditive method and exhibits high connection reliability, by a simple process. Another object of the invention is to provide an advanced multilayer wiring substrate.

As a result of intensive studies on the problems, the present inventors have found that the above objects may be achieved by the means shown below.
<1> A method for producing a multilayer wiring substrate, the method including: (1) forming a laminated body having an insulating resin layer and a polymer adhesive layer, on a surface of a first wiring substrate having a metal wiring thereon, in which the polymer adhesive layer contains a polymer precursor having a functional group, that forms an interaction with a plating catalyst or a precursor thereof, and a reactive group capable of forming a bond with an adjacent layer on the first wiring substrate side; (2) applying energy in a patterned manner to a region outside of a via connection portion on the surface of the laminated body, to form a pattern-shaped polymer adhesive layer, in which the polymer precursor is bonded to the insulating resin layer, at the energy-applied region; (3) applying a plating catalyst or a precursor thereof to the patterned polymer adhesive layer, and carrying out a first electroless plating treatment, to form a second metal wiring on the surface of the patterned polymer adhesive layer; and (4) forming a via using the patterned second metal wiring as a mask, and subsequently carrying out a desmear treatment.
<2> The method for producing a multilayer wiring substrate according to the item <1>, wherein: the polymer precursor includes a cyano group and a polymerizable group; an adhesion auxiliary layer is disposed between the insulating resin layer and the polymer adhesive layer; and the processes (3) and (4) are performed in a manner such that a ratio of Ra of the surface of the patterned polymer adhesive layer on the side of the second metal wiring to Ra of an inner face of the via is from 0.05 to 0.50.
<3> The method for producing a multilayer wiring substrate according to the item <1> or <2> further including: (5) carrying out a second electroless plating treatment or an electrically conductive paste filling treatment at the formed via portion, to electrically connect the metal wiring on the surface of the first wiring substrate and the second metal wiring that has been formed on the surface of the pattern-shaped polymer adhesive layer.
<4> The method for producing a multi layer wiring substrate according to any one of the items <1> to <3> further including: (6) forming a plating resist layer on the surface of the second metal wiring that has been formed on the surface of the patterned polymer adhesive layer; (7) patterning the plating resist layer; (8) carrying out electroplating utilizing the plating resist layer, to form a wiring pattern; and (9) after the formation of the wiring pattern, removing the plating resist layer corresponding to a non-wiring pattern portion, which has been used to conduct electrical connection in the electroplating.
<5> The method for producing a multilayer wiring substrate according to any one of the items <1> to <4>, wherein the laminated body further includes an adhesion auxiliary layer between the insulating resin layer and the polymer adhesive layer, the polymer adhesive layer including the polymer precursor including a functional group that forms an interaction with a plating catalyst or a precursor thereof; and a polymerizable group as the reactive group capable of forming a bond with an adjacent layer on the first wiring substrate side.
<6> The method for producing a multilayer wiring substrate according to any one of the items <1> to <5>, wherein the (1) process of forming a laminated body includes transferring a sheet that has been formed by forming the polymer adhesive layer on the insulating resin layer in advance, onto the surface of the first wiring substrate.
<7> The method for producing a multilayer wiring substrate according to any one of the items <1> to <6>, wherein the second metal wiring formed by the first electroless plating treatment is a copper film, and a thickness of the formed copper film is from 0.2 μm to 2 μm.
<8> The method for producing a multilayer wiring substrate according to any one of the items <1> to <7>, wherein the (5) process of carrying out a second electroless plating treatment or an electrically conductive paste filling treatment at the formed via portion, to electrically connect the metal wiring on the surface of the first wiring substrate and the second metal wiring that has been formed on the surface of the patterned polymer adhesive layer is carried out before or after the (6) process of forming a plating resist layer on the surface of the second metal wiring that has been formed on the surface of the patterned polymer adhesive layer and the (7) process of patterning the plating resist layer.
<9> The method for producing a multilayer wiring substrate according to any one of the items <1> to <8>, wherein the polymer precursor includes a cyano group and a polymerizable group.
<10> The method for producing a multilayer wiring substrate according to any one of the items <1> to <9>, wherein the polymer precursor having a functional group that forms an interaction with a plating catalyst or a precursor thereof, and a polymerizable group includes a copolymer containing a unit represented by Formula (1) described below and a unit represented by Formula (2) described below.
<11> The method for producing a multilayer wiring substrate according to any one of the items <1> to <10>, wherein the polymer precursor having a functional group that forms an interaction with a plating catalyst or a precursor thereof, and a polymerizable group has a weight average molecular weight of 20,000 or more.
<12> A multilayer wiring substrate including a laminated body including an insulating resin layer and a patterned polymer adhesive layer, on a surface of a first wiring substrate including a metal wiring thereon, in which the patterned polymer adhesive layer includes a polymer including a cyano group as a functional group that forms an interaction with a plating catalyst or a precursor thereof, wherein the laminated body includes an adhesion auxiliary layer between the insulating resin layer and the patterned polymer adhesive layer, and the laminated body includes a via portion which is not covered with the insulating resin layer and the patterned polymer adhesive layer, and a second metal wiring on a surface of the patterned polymer adhesive layer, and a ratio of Ra of the surface of the patterned polymer adhesive layer on the side of the second wiring to Ra of an inner face of the via portion is from 0.05 to 0.50.

### BRIEF DESCRIPTION OF THE DRAWINGS

FIGS. 1A to 1F are schematic cross-sectional views showing one example of a process for producing a multilayer wiring substrate having, on each of both sides of a core substrate, two layers of wirings which are electrically connected with each other.

FIGS. 2A to 2E are schematic cross-sectional views showing one example of a process for producing a multilayer wiring substrate which is formed by laminating an additional wiring, using the method for producing a multilayer wiring substrate of the present invention.

FIGS. 3A to 3D are schematic cross-sectional views showing one part of a process of a second exemplary embodiment in the method for producing a multilayer wiring substrate of the present invention.

FIGS. 4A to 4C are schematic cross-sectional views showing one example of another embodiment for forming a multilayer wiring by using a laminated body that is used in the method for producing a multilayer wiring substrate of the present invention.

### DETAILED DESCRIPTION OF THE INVENTION

Hereinafter, the present invention is described in detail.

It should be noted that the term “via” used in the present invention has the same meaning as “via hole”, and is also used to refer to a through hole that is formed in order to electrically connect the wiring lines.

According to the present invention, a method for producing a multilayer wiring substrate, which is suitable for forming a fine wiring in accordance with a semiadditive method and exhibits high connection reliability, by a simple process may be provided.

Specifically, according to the present invention, by performing polymerization using a polymer compound precursor having a functional group that forms an interaction with a plating catalyst or a precursor thereof, and a polymerizable group, a second metal wiring which exhibits excellent adhesion to a first metal wiring and functions as a conformal mask in the formation of via can be readily formed. In addition to this, since the method of the invention enables a desmear treatment to be carried out without fail, improvement in the reliability in the connection between the first wiring and the second wiring may also be achieved.

Especially, according to the items <2> and <11> of the present invention, irregularities of the edge portion of the second wiring can be improved, and still an anchoring effect at the via-portion can be secured.

The method for producing a multilayer wiring substrate of the present invention is typically exemplified in that the method includes: (1) forming a laminated body having an insulating resin layer and a polymer adhesive layer, on a surface of a first wiring substrate including a metal wiring thereon, in which the polymer adhesive layer contains a polymer precursor having a functional group that forms an interaction with a plating catalyst or a precursor thereof, and a reactive group capable of forming a bond with an adjacent layer on the first wiring substrate side; (2) applying energy in a patterned manner to a region outside of a via connection portion on the surface of the laminated body, to form a patterned polymer adhesive layer, which is bonded to the insulating resin layer, at the energy-applied region; (3) applying a plating catalyst or a precursor thereof to the patterned polymer adhesive layer, and carrying out a first electroless plating treatment, to form a second metal wiring on the surface of the patterned polymer adhesive layer; and (4) forming a via using the patterned metal film as a mask, and subsequently carrying out a desmear treatment.

The processes in the present invention are each described with reference to the drawings.

Process (1) of Forming a Laminated Body Having an Insulating Resin Layer and a Polymer Adhesive Layer, on a Surface of a First Wiring Substrate Including a Metal Wiring thereon, in which the Polymer Adhesive Layer Contains a Polymer Precursor Having a Functional Group that Forms an Interaction with a Plating Catalyst or a Precursor thereof, and a Reactive Group capable of Forming a Bond with an Adjacent Layer on the First Wiring Substrate Side

In process (1), a laminated body which becomes the basis of the multilayer wiring substrate is formed.

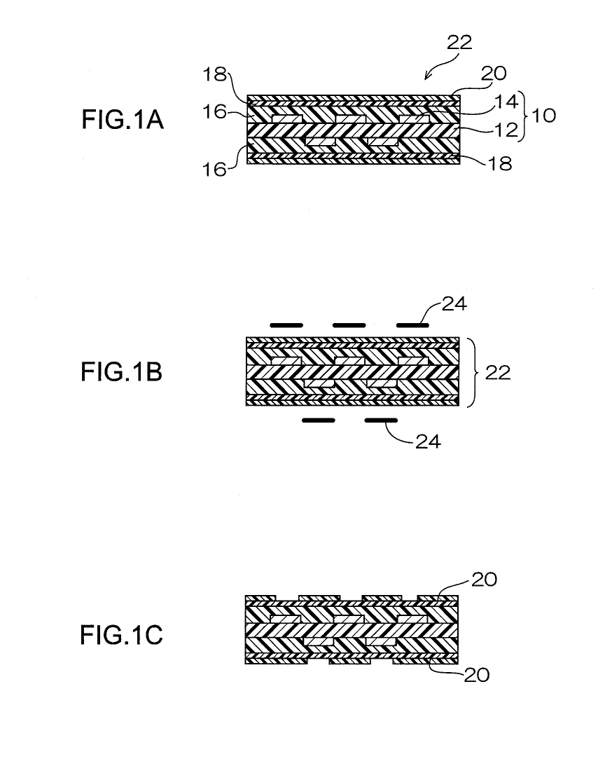

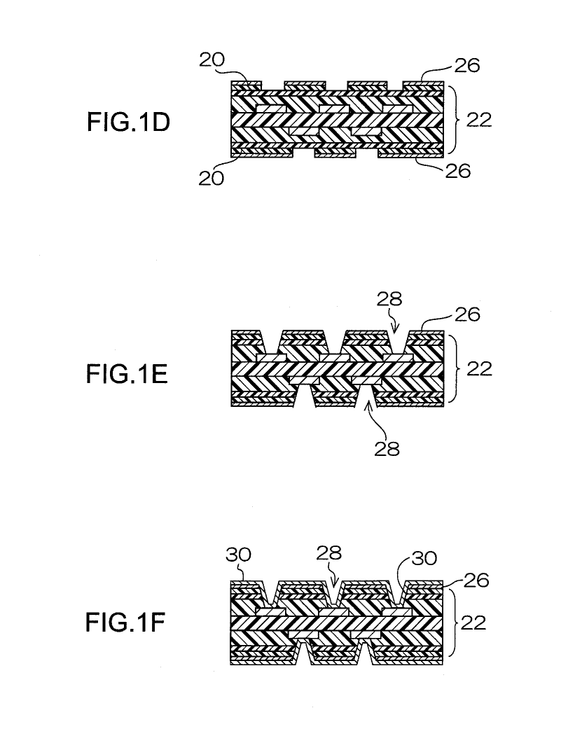

First, as shown in FIG. 1A, a first wiring substrate 10 having a substrate 12 and a wiring 14 formed on the substrate is prepared. Hereinafter, the first wiring substrate 10 may sometimes be referred to as “core substrate”.

Examples of the core substrate 10 used in the present invention include, typically, those formed by a substractive method utilizing an etching treatment and those formed by a semiadditive method utilizing electroplating. A core substrate formed by any of methods of construction may be used.

As the core base material that forms the core substrate, a copper clad laminate (CCL) is typically used, and as the insulating layer, a glass epoxy material, a polyimide film, a polyamide film, a liquid crystal film, an aramide material, or the like may be used. Examples of the copper clad laminate include those prepared by heating and pressing a copper foil to the insulating layer through an adhesive agent layer; those prepared by heating and pressing the insulating layer itself to a copper foil; those prepared by casting an insulating material onto a copper foil and then heating; and those prepared by subjecting the insulating layer to a surface treatment, then forming a seed layer by sputtering using nichrome or the like, and then forming a conductor layer by sputtering or plating of copper or the like.

Insulating Resin Layer

Firstly, an insulating resin layer 16 is formed on the surface of the core substrate 10. The insulating resin layer 16 may be formed by any method, and any of a coating method or a laminating method may be applied.

A known insulating resin composition may be used as the insulating resin for forming the insulating resin layer used in the present invention. For the insulating resin composition, in addition to the main resin, various kinds of additives may be used in combination according to the purposes. For example, a means of adding a polyfunctional acrylate monomer for the purpose of enhancing the strength of the insulating resin layer, a means of adding inorganic or organic particles for the purpose of enhancing the strength of the insulating resin layer and improving the electrical characteristics, or the like can be used.

It should be noted that the term “insulating resin” used in the present invention means a resin having an insulating property sufficient to be used in a known insulating film or insulating layer, and a resin having an insulating property according to the purpose can be used in the present invention, even though it is not a perfect insulator.

The insulating resin may be a thermosetting resin, a thermoplastic resin, or a mixture thereof. Specifically, examples of the thermosetting resin include epoxy resins, phenolic resins, polyimide resins, polyester resins, bismaleimide resins, polyolefin-based resins, isocyanate-based resins, and the like.

Examples of the thermoplastic resins include phenoxy resins, polyether sulfone, polysulfone, polyphenylene sulfone, polyphenylene sulfide, polyphenyl ether, polyether imide, and the like.

Other thermoplastic resins include 1,2-bis(vinylphenylene)ethane resin, or a modified resin obtained from the 1,2-bis(vinylphenylene)ethane resin and a polyphenylene ether resin (described in Satoru Amou et al., Journal of Applied Polymer Science, Vol. 92, pp. 1252-1258 (2004)), liquid crystal polymers (for example, VECSTAR, trade name, manufactured by Kuraray Co., Ltd.), fluororesins (PTFE), and the like.

The thermoplastic resin and the thermosetting resin may be used alone or in combination for the purpose of compensating the defects of each resin to achieve better effects. For example, since a thermoplastic resin such as polyphenylene ether (PPE) has low resistance to heat, alloying with a thermosetting resin or the like may be carried out, such as alloying of PPE with an epoxy resin or a triallyl isocyanate resin, or alloying of a PPE resin to which a polymerizable functional group has been introduced with another thermosetting resin. Further, a cyanate ester is a resin that exhibits the most excellent dielectric properties among the thermosetting resins, but is rarely used alone and mainly used as a modified resin of epoxy resins, maleimide resins, thermoplastic resins and the like. Details of these resins are described in “Denshi Gijutsu (Electronic Technology)” No. 2002/9, p. 35. Furthermore, a mixture containing an epoxy resin and/or a phenolic resin as a thermosetting resin, and a phenoxy resin and/or polyethersulfone (PES) as a thermoplastic resin, may also be used for the purpose of improving dielectric properties.

The insulating resin composition may include a compound containing a polymerizable double bond in order to promote crosslinking reaction. Specific examples of the compound include an acrylate or methacrylate compound, particularly preferably a polyfunctional acrylate or methacrylate compound. Other applicable compounds containing a polymerizable double bond include those obtained by subjecting a part of a thermosetting resin or a thermoplastic resin (for example, an epoxy resin, a phenolic resin, a polyimide resin, a polyolefin resin, or a fluororesin) to a (meth)acrylation reaction using methacrylic acid, acrylic acid or the like.

A composite of a resin and other component may also be used as the insulating resin composition for the purpose of reinforcing the properties of a resin film, such as mechanical strength, heat resistance, weather resistance, flame retardancy, water resistance or electrical properties. Examples of the material that may be used for producing a composite include paper, glass fiber, silica particles, phenolic resins, polyimide resins, bismaleimide triazine resins, fluororesins, polyphenylene oxide resins, or the like.

Further, the insulating resin composition may be compounded with, if necessary, one or more kind of filler for use in general resin materials for wiring substrates. Examples of the filler include inorganic fillers such as silica, alumina, clay, talc, aluminum hydroxide and calcium carbonate, and organic fillers such as cured epoxy resin, crosslinked benzoguanamine resin and crosslinked acrylic polymer. Among them, silica is preferably used as the filler.

The insulating resin composition may also include one or more additive of various kinds as necessary, such as a colorant, a flame retardant, a tackifier, a silane coupling agent, an antioxidant, an ultraviolet absorbent, and the like.

When these materials are added to the insulating resin composition, the total amount of the same is preferably 1 to 200% by mass, more preferably 10 to 80% by mass, with respect to the amount of the resin. If the above amount is less than 1% by mass, effects on reinforcement of the aforementioned properties may not be achieved, while if the above amount is more than 200% by mass, properties that are inherent to the resin, such as strength, may be deteriorated.

The thickness of the insulating resin layer may be selected as appropriate according to the purpose of use of the multilayer wiring substrate, but the thickness is generally from about 5 μm to about 150 μm, and preferably in a range of from 7 μm to 100 μm.

Adhesion Auxiliary Layer

Next, an adhesion auxiliary layer 18 is formed on the surface of the insulating resin layer 16. In a case in which adhesion between the insulating resin layer 16 and the polymer adhesive layer 20 described below is satisfactory, the formation of the adhesion auxiliary layer 18 may be omitted.

By providing the adhesion auxiliary layer 18, the bonding reaction for forming a bond between the surface of the adhesion auxiliary layer 18 and the polymer adhesive layer 20 can be efficiently carried out. The adhesion auxiliary layer 18 according to the present invention is useful, in the case of using a method of providing an active species that serves as an initiation point of the bonding reaction with the polymer adhesive layer and generating a bond with the adhesion auxiliary layer using the active species as the starting point, for example, a surface graft polymerization method or the like. Specifically, a polymerization initiation layer containing a polymerization initiator, a polymerization initiation layer having a functional group capable of initiating polymerization, or the like can be used. When such adhesion auxiliary layer 18 is provided on the surface of the insulating resin layer 16, active points may be efficiently generated, and more bonds with the polymer adhesive layer can be generated, and therefore, it is useful for the formation of the polymer adhesive layer 20 described below.

Examples of the adhesion auxiliary layer according to the present invention include a layer containing a polymer compound and a polymerization initiator, a layer containing a polymerizable compound and a polymerization initiator, a layer having a functional group capable of initiating polymerization, a layer that generates an active cite capable of initiating polymerization by application of a certain energy, and a layer that forms a chemical bond with the polymer adhesive layer by application of a certain energy.

The adhesion auxiliary layer according to the present invention can be formed by dissolving necessary components in a solvent capable of dissolution, applying the resulting solution on the surface of a substrate by a method such as coating, and forming a cured film by heating or photoirradiation.

For example, in a case in which the insulating resin layer 16 to be formed on the first wiring substrate 10 in the present invention includes a known insulating resin which has been used as a material of a multilayer laminate, a build up substrate, or a flexible substrate, it is preferable to use, as the resin composition used for the formation of the adhesion auxiliary layer 18, an insulating resin composition that is substantially the same as that used for the formation of the insulating resin layer 16, from the viewpoint of the adhesion to the insulating resin layer 16.

Hereinafter, embodiments of the adhesion auxiliary layer formed from an insulating resin composition are described.

The insulating resin composition that is used for forming the adhesion auxiliary layer may include the same electrically insulating resin that composes the insulating resin layer 16 formed on the first wiring substrate 10, or may include a different resin therefrom, but it is preferable to use a resin having similar thermal properties to that of the resin used for the insulating resin layer 16, such as glass transition temperature, elasticity or linear expansion coefficient. Specifically, for example, it is preferable to use the same resin as that used for the resin that composes the insulating resin layer 16 formed on the first wiring substrate 10, from the viewpoint of adhesion.

Further, the insulating resin composition may include inorganic or organic particles for the purpose of increasing the strength of adhesion auxiliary layer 18 or improving the electric characteristics.

The insulating resin may be a thermosetting resin, a thermoplastic resin or a mixture thereof.

Specific examples of the thermosetting resin include an epoxy resin, a phenol resin, a polyimide resin, a polyester resin, a bismaleimide resin, a polyolefin resin, and an isocyanate resin.

Specific examples of the thermoplastic resin include a phenoxy resin, polyethersulfone, polysulfone, polyphenylenesulfone, polyphenylenesulfide, polyphenylether, and polyetherimide.

Each of the thermosetting resin and the thermoplastic resin may be used alone or in combination of two or more. Mixing two or more resins may be effective to exhibit superior effects by compensating the shortcomings of each other.

The insulating resin used for the adhesion auxiliary layer may be a resin having a skeleton that generates an active cite capable of forming an interaction with a plating catalyst-receptive photosensitive resin composition. One example thereof is polyimide resins having a polymerization initiation site in the skeleton, which are described in paragraphs [0018] to [0078] of JP-A No. 2005-307140.

Further, the adhesion auxiliary layer may include a compound having a polymerizable double bond in order to promote the crosslinking in the layer. Specific examples of the compound include an acrylate or methacrylate compound, particularly preferably a polyfunctional acrylate or methacrylate compound. Other applicable compounds having a polymerizable double bond include those obtained by acrylating or methacrylating a part of a thermosetting resin or a thermoplastic resin (for example, an epoxy resin, a phenolic resin, a polyimide resin, a polyolefin resin, or a fluororesin), using methacrylic acid, acrylic acid or the like.

The adhesion auxiliary layer may include a compound of various kinds according to purposes to such an extent that the effects of the invention is not impaired.

Specific examples thereof include a compound that can lessen the stress such as a rubber or SBR latex, and a compound that can improve the film property such as a binder, a plasticizer, a surfactant, or a viscosity adjuster.

A composite of a resin and other component may also be used for the adhesion auxiliary layer, for the purpose of reinforcing the properties of a resin film, such as mechanical strength, heat resistance, weather resistance, flame retardancy, water resistance or electrical properties. Examples of the material that may be used for producing a composite include paper, glass fiber, silica particles, phenolic resins, polyimide resins, bismaleimide triazine resins, fluororesins, polyphenylene oxide resins, or the like.

Further, the adhesion auxiliary layer may include, as necessary, one or more kinds of filler that is used in typical resin materials for wiring substrates. Examples of the filler include inorganic fillers such as silica, alumina, clay, talc, aluminum hydroxide and calcium carbonate, and organic fillers such as cured epoxy resin, crosslinked benzoguanamine resin and crosslinked acrylic polymer.

The adhesion auxiliary layer may also include one or more kinds of additive as necessary, such as a colorant, a flame retardant, a tackifier, a silane coupling agent, an antioxidant, an ultraviolet absorbent, and the like.

When these materials are added to the adhesion auxiliary layer, each of these material is preferably from 0 to 200% by mass, and more preferably from 0 to 80% by mass, with respect to the amount of the resin as a main component. If the materials included in the layer that contacts the adhesion auxiliary layer have the same or similar physical values with respect to heat or electricity, these additives may not necessarily be included in the adhesion auxiliary layer. If the amount of the additives is more than 200% by mass, properties that are inherent to the resin, such as strength, may be deteriorated.

The adhesion auxiliary layer preferably includes an active species (compound) that generates an active site capable of forming an interaction with the polymer precursor. The active cite is generated upon application of energy, preferably light (such as ultraviolet rays, visible rays or X rays), plasma (such as oxygen, nitrogen, carbon dioxide or argon), heat, electricity, or the like. Further, it is also possible to generate an active sited by chemically decomposing the surface of the adhesion auxiliary layer with an oxidizable liquid (potassium permanganate solution).

Examples of the active species include a thermal polymerization initiator or a photo polymerization initiator. Specifically, these are described in paragraphs [0043] and [0044] of JP-A No. 2007-154306. The amount (solid content) of polymerization initiator included in the adhesion auxiliary layer is preferably from 0.1 to 50 mass %, and more preferably from 1.0 to 30 mass %.

The thickness of the adhesion auxiliary layer 18 according to the present invention is generally in a range of from 0.1 μm to 10 μm, and preferably in a range of from 0.2 μm to 5 μm, from the viewpoints of realizing sufficient polymerization initiation ability and maintaining physical properties of the film to prevent film peeling or the like. On the basis of mass after being dried, the thickness is preferably from 0.1 g/m² to 20 g/m², more preferably from 0.1 g/m² to 15 g/m², and even more preferably from 0.1 g/m² to 2 g/m².

The solvent used for the application of the adhesion auxiliary layer is not particularly limited as long as it can dissolve the components of the composition, but is preferably a solvent having a boiling point that is not very high, such as those having a boiling point of about 40 to 150° C.

Specific examples of the solvent that may be used include cyclohexanone or methyl ethyl ketone described in paragraph [0045] of JP-A No. 2007-154306. The solvent may be used alone or in combination of two or more kinds. The appropriate solid content concentration of the coating liquid is 2 to 50 mass %.

In the invention, as mentioned above, it is preferable to perform pre-curing by applying heat and/or light at the time of disposing a composition for forming the above-described adhesion auxiliary layer onto an insulating resin by coating or the like, and removing the solvent to form a film. It is particularly preferable to perform pre-curing by irradiating the layer with light after drying the layer by heating, since if the pre-curing is performed, curing of the polymerizable compound is promoted to some extent in advance, and exfoliation of the whole layers including the adhesion auxiliary layer after completion of polymer adhesion layer on the adhesion auxiliary layer may be effectively suppressed.

The temperature and time for the heating may be appropriately selected under the conditions such that the solvent may be sufficiently dried. However, from the viewpoint of production suitability, the heating conditions are preferably selected in a manner such that the drying temperature is 200° C. or less and the drying time is 60 minutes or less, and the drying temperature of from 40 to 100° C. and the drying time of 20 minutes or less are more preferably selected as the heating conditions.

The adhesion auxiliary layer may be formed on a surface of the resin film (base material) on which the polymer layer is to be formed, by a known technique such as coating, transferring or printing.

When the adhesion auxiliary layer is formed by a transfer method, the formation may be performed by preparing a transfer laminate including two-layer constitution composed of the polymer adhesive layer and the adhesion auxiliary layer, and then transferring the laminate to a surface of the base material by a lamination method.

Polymer Adhesive Layer

The polymer adhesive layer contains a polymer precursor (hereinafter, may be suitably referred to as a “specific polymer precursor”) having a functional group that interacts with a plating catalyst or a precursor thereof to form a coordination bond and a reactive group (for example, a polymerizable group) capable of forming a bond with an adjacent layer on the first wiring substrate side. In the present invention, the term “an adjacent layer on the first wiring substrate side” of the polymer adhesive layer refers to an “adhesion auxiliary layer” which is adjacent to the polymer adhesive layer and is disposed at the first wiring substrate side, and in the case of an embodiment in which an adhesion auxiliary layer is not included, the term refers to an “insulating resin layer”.

The specific polymer precursor has a functional group that interacts with a plating catalyst or a precursor thereof to form a coordination bond (hereinafter, may merely be referred to as an “interactive group”). Therefore, the specific polymer precursor may efficiently adsorb the plating catalyst or the like. Further, the specific polymer precursor is a compound having a reactive group (for example, a polymerizable group) capable of forming a bond with the adhesion auxiliary layer or the insulating resin layer. When an energy is applied, the specific polymer precursor directly and chemically bonds to the adjacent insulating resin layer 16 or adhesion auxiliary layer 18, to form a polymer compound and may form a resin layer for plating (polymer adhesive layer) 20 which is tightly bonded to the adjacent insulating resin layer 16 or adhesion auxiliary layer 18.

The polymer adhesive layer 20 described below preferably satisfies any of the following conditions 1 to 4, and more preferably satisfies all of them.

Condition 1: saturated water absorption coefficient as measured under an environment of 25° C. and 50% relative humidity is from 0.01% by mass to 10% by mass

Condition 2: saturated water absorption coefficient as measured under an environment of 25° C. and 95% relative humidity is from 0.05% by mass to 20% by mass

Condition 3: water absorption coefficient as measured after immersing the polymer adhesive layer in boiling water at 100° C. for 1 hour is from 0.1% by mass to 30% by mass

Condition 4: surface contact angle as measured after adding dropwise 5 μL of distilled water onto the polymer adhesive layer and allowing the droplet to stand still for 15 seconds, under an environment of 25° C. and 50% relative humidity, is from 50 degrees to 150 degrees.

As an example of the polymer precursor in the present invention, a compound having a polymerizable group and an interactive group is described.

As the compound having a polymerizable group and an interactive group in the present invention, it is preferable to use a compound having a polymerizable group and an interactive group, as well as having low water absorbing property and high hydrophobicity, such that the resin composition layer including the formed polymer compound satisfies all of the conditions 1 to 4.

The interactive group in this compound is preferably a non-dissociative functional group. The term “non-dissociative functional group” means a functional group which does not generate a proton by dissociation of the functional group.

Such a functional group has a function of forming an interaction with a plating catalyst or a precursor thereof, but does not have water absorbing property and hydrophilicity as high as those of a dissociative polar group (hydrophilic group). Accordingly, a resin composition layer including the polymer compound having the above functional group can satisfy any of the conditions 1 to 4 described above.

The polymerizable group in the present invention is a functional group capable of forming a bond between the compounds having a polymerizable group and an interactive group, or a bond between a compound having a polymerizable group and an interactive group and the adjacent layer which is adjacent to the polymer adhesive layer and is provided at the first wiring substrate side, specifically, the adhesion auxiliary layer or the insulating resin layer, by application of energy. Specific examples of the polymerizable group include a vinyl group, a vinyloxy group, an allyl group, an acryloyl group, a methacryloyl group, an oxetane group, an epoxy group, an isocyanate group, a functional group containing an active hydrogen, and an active group in an azo compound.

Preferable examples of the interactive group in the present invention include, specifically, a group capable of forming a coordination with a metal ion, a nitrogen-containing functional group, a sulfur-containing functional group, and an oxygen-containing functional group. Specific examples thereof include: a nitrogen-containing functional group such as an imido group, a pyridine group, a tertiary amino group, an ammonium group, a pyrrolidone group, an amidino group, a group containing a triazine ring structure, a group containing an isocyanuric structure, a nitro group, a nitroso group, an azo group, a diazo group, an azido group, a cyano group, or a cyanate group (R—O—CN); an oxygen-containing functional group such as an ether group, a carbonyl group, an ester group, a group containing an N-oxide structure, a group containing an S-oxide structure, or a group containing an N-hydroxy structure; a sulfur-containing functional group such as a thioether group, a thioxy group, a sulfoxide group, a sulfone group, a sulfite group, a group containing a sulfoxyimine structure, a sulfonium group, a sulfoxonium group, or a group containing a sulfonic acid ester structure; a phosphorus-containing functional group such as a phosphine group; a group containing a halogen atom such as chlorine or bromine; and an unsaturated ethylene group. Further, an imidazole group, a urea group, or a thiourea group may also be used as far as the embodiment exhibits a non-dissociation property in relation with adjacent atoms or atomic groups.

Among them, from the viewpoints of having high polarity and high adsorption capacity to a plating catalyst or the like, an ether group (more specifically, a group having a structure represented by —O—(CH₂)ₙ—O— (n represents an integer of from 1 to 5)) or a cyano group is particularly preferable, and a cyano group is most preferable.

In general, as the polarity gets higher, the water absorption coefficient tends to be higher. However, since the cyano groups interact with each other so as to cancel out the polarity thereof in the resin composition layer, the film becomes dense and the polarity of the resin composition layer as a whole decreases, whereby the water absorbing property becomes lower. Further, a catalyst is adsorbed by means of a good solvent used for the resin composition layer, and thus the cyano groups are solvated and the interaction between the cyano groups is canceled, thereby enabling the cyano groups to interact with the plating catalyst. For the reasons described above, the resin composition layer having a cyano group is preferable in view of achieving both of contradictory properties of low moisture absorption and satisfactory interaction with the plating catalyst.

The interactive group in the present invention is more preferably a cyanoalkyl group. The reason for the above is as follows. In an aromatic cyano group, electrons are attracted to the aromatic ring, and thus, the donating property of unpaired electrons that play an important role for the adsorptivity to a plating catalyst or the like may be decreased. In contrast, in a cyanoalkyl group, such an aromatic ring is not bonded thereto. Therefore, a cyanoalkyl group is preferable from the viewpoint of the adsorptivity to a plating catalyst or the like.

In the present invention, the specific polymer precursor having a polymerizable group and an interactive group may be in the form of a monomer, a macromonomer, or a polymer. Among them, from the viewpoints of the ability to form a resin composition layer and the easiness of control, it is preferable to use a polymer (polymer having a polymerizable group and an interactive group).

The polymer having a polymerizable group and an interactive group is preferably a polymer obtained by introducing an ethylene addition polymerizable unsaturated group (a polymerizable group) such as a vinyl group, an allyl group, or a (meth)acryl group ((meth)acryloyl group), as a polymerizable group, into a homopolymer or copolymer obtained by using a monomer having an interactive group. The polymer having a polymerizable group and an interactive group is a polymer having a polymerizable group at least at the terminal of the main chain or in the side chain, and is more preferably a polymer having a polymerizable group in the side chain.

As the monomer having an interactive group, which is used to obtain the polymer having a polymerizable group and an interactive group, any monomer can be used as long as the monomer has a non-dissociative functional group as described above.

One type of these monomers may be used alone, or two or more types of these monomers may be used in combination.

In the polymer having a polymerizable group and an interactive group, a unit derived from the monomer having an interactive group is preferably contained in the polymer having a polymerizable group and an interactive group in an amount of from 50 mol % to 95 mol %, and more preferably from 40 mol % to 80 mol %, from the viewpoint of the ability to form an interaction with a plating catalyst or a precursor thereof.

Further, in the preparation of the polymer having a polymerizable group and an interactive group, an additional monomer other than the above-described monomer having an interactive group may be used in order to lower the water absorbing property, and further, in order to enhance the hydrophobicity. As the additional monomer, a generally used polymerizable monomer may be used, and examples thereof include a diene monomer and an acrylic monomer. Among them, an acrylic monomer of unsubstituted alkyl is preferable. Specifically, tertiary butyl acrylate, 2-ethylhexyl acrylate, butyl acrylate, cyclohexyl acrylate, benzyl methacrylate, or the like may be preferably used.

Such polymers having a polymerizable group and an interactive group may be synthesized as follows.

Examples of the synthesis method include: i) a method of performing copolymerization using a monomer having an interactive group and a monomer having a polymerizable group; ii) a method of performing copolymerization using a monomer having an interactive group and a monomer having a double bond precursor, followed by treatment with a base or the like to introduce a double bond; and iii) a method of allowing a polymer having an interactive group to react with a monomer having a polymerizable group, thereby introducing a double bond (introducing a polymerizable group). From the viewpoint of suitability for synthesis, ii) a method of performing copolymerization using a monomer having an interactive group and a monomer having a double bond precursor, followed by treatment with a base or the like to introduce a double bond and iii) a method of allowing a polymer having an interactive group to react with a monomer having a polymerizable group, thereby introducing a double bond are preferable.

As the monomer having an interactive group, which is used in the synthesis of the polymer having a polymerizable group and an interactive group, a monomer substantially the same as the above-described monomer having an interactive group may be used. One type of the monomers may be used alone, or two or more types of the monomers may be used in combination.

Examples of the monomer having a polymerizable group, which may be used for the copolymerization with the monomer having an interactive group, include allyl (meth)acrylate, and 2-allyloxyethyl methacrylate.

Further, examples of the monomer having a double bond precursor include 2-(3-chloro-1-oxopropoxy)ethyl methacrylate, and 2-(3-bromo-l-oxopropoxy)ethyl methacrylate.

Furthermore, examples of the monomer having a polymerizable group, which may be used for introducing an unsaturated group by utilizing a reaction with a functional group, such as a carboxyl group, an amino group, salts of these groups, a hydroxyl group, or an epoxy group, in the polymer having an interactive group, include (meth)acrylic acid, glycidyl (meth)acrylate, allyl glycidyl ether, and 2-isocyanatoethyl (meth)acrylate.

In a case in which the specific polymer precursor is a polymer, the weight average molecular weight of the polymer to be used is preferably from 1,000 to 700,000, and more preferably from 2,000 to 300,000. Particularly, from the viewpoint of polymerization sensitivity, it is preferable that the weight average molecular weight is 20,000 or more. Further, regarding the degree of polymerization of the polymer to be used, it is preferable to use a polymer of 10-mer or more, and more preferably a polymer of 20-mer or more. Furthermore, it is preferable to use a polymer of a polymer of 7,000-mer or less, more preferably a polymer of 3,000-mer or less, even more preferably a polymer of 2,000-mer or less, and particularly preferably a polymer of 1,000-mer or less.

The content of the specific polymer precursor (for example, a cyano group-containing polymerizable compound) with respect to the polymer adhesive layer is preferably from 2% by mass to 100% by mass in terms of the solid content, and more preferably in a range of from 5% by mass to 90% by mass.

It is preferable that the polymer adhesive layer according to the present invention contains at least one of a synthetic rubber or an epoxy acrylate monomer, in addition to the specific polymer precursor. By adding at least one of these compounds, with respect to the specific polymer precursor, advantages of further improving the ability to form a high accuracy pattern, flexibility of the film, adhesion to the plated film, or the like may be provided, even under a severe condition such as high humidity.

Hereinafter, the specific polymer precursor according to the present invention, and further, as a specific example, a polymer having a cyano group (hereinafter, referred to as “cyano group-containing polymerizable polymer”) are described.

The cyano group-containing polymerizable polymer in the present invention is preferably a copolymer containing, for example, a unit represented by the following Formula (1) and a unit represented by the following Formula (2).

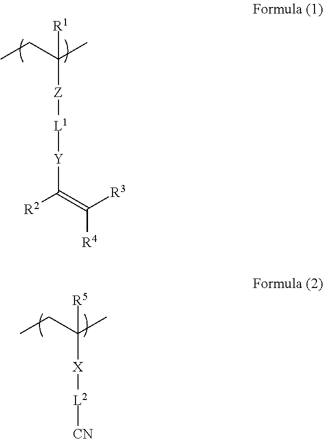

In Formula (1) and Formula (2) above, each of R¹ to R⁵ independently represents a hydrogen atom or a substituted or unsubstituted alkyl group; each of X, Y, and Z independently represents a single bond, a substituted or unsubstituted divalent aliphatic or aromatic hydrocarbon group, an ester group, an amido group, or an ether group; each of L¹ and L² independently represents a substituted or unsubstituted divalent aliphatic or aromatic hydrocarbon group.

In a case in which R¹ to R⁵ represents a substituted or unsubstituted alkyl group, examples of the unsubstituted alkyl group include a methyl group, an ethyl group, a propyl group, and a butyl group, and examples of the substituted alkyl group include a methyl group, an ethyl group, a propyl group, or a butyl group, each of which is substituted with a methoxy group, a hydroxyl group, a chlorine atom, a bromine atom, a fluorine atom, or the like.

R¹ preferably represents a hydrogen atom, a methyl group, or a methyl group substituted with a hydroxyl group or a bromine atom.

R² preferably represents a hydrogen atom, a methyl group, or a methyl group substituted with a hydroxyl group or a bromine atom.

R³ preferably represents a hydrogen atom.

R⁴ preferably represents a hydrogen atom.

R⁵ preferably represents a hydrogen atom, a methyl group, or a methyl group substituted with a hydroxyl group or a bromine atom.

In a case in which X, Y, or Z represents a substituted or unsubstituted divalent aliphatic or aromatic hydrocarbon group, examples of the divalent aliphatic or aromatic hydrocarbon group include a substituted or unsubstituted divalent aliphatic hydrocarbon group and a substituted or unsubstituted divalent aromatic hydrocarbon group.

Preferably examples of the substituted or unsubstituted divalent aliphatic hydrocarbon group include a methylene group, an ethylene group, a propylene group, a butylene group, and those groups each of which is substituted with a methoxy group, a hydroxyl group, a chlorine atom, a bromine atom, a fluorine atom, or the like.

Preferably examples of the substituted or unsubstituted divalent aromatic hydrocarbon group include an unsubstituted phenylene group and a phenylene group substituted with a methoxy group, a hydroxyl group, a chlorine atom, a bromine atom, a fluorine atom, or the like.

Among them, —(CH₂)ₙ— (n represents an integer of from 1 to 3) is preferable, and —CH₂— is more preferable.

L¹ preferably represents a divalent aliphatic or aromatic hydrocarbon group having a urethane bond or a urea bond, and more preferably represents a divalent aliphatic or aromatic hydrocarbon group having a urethane bond. In particular, a group having a total number of carbon atoms of from 1 to 9 is preferred. Herein, the total number of carbon atoms of L¹ means a total number of carbon atoms contained in the substituted or unsubstituted divalent aliphatic or aromatic hydrocarbon group represented by L¹.

More specifically, L¹ preferably has a structure represented by the following Formula (1-1) or Formula (1-2).

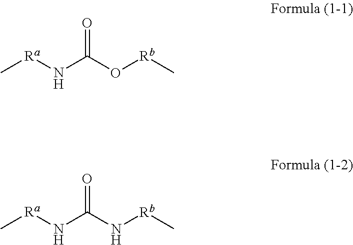

In Formula (1-1) and Formula (1-2) above, each of R^{a} and R^{b} independently represents a divalent aliphatic or aromatic hydrocarbon group which is formed by using two or more atoms selected from the group consisting of a carbon atom, a hydrogen atom, and an oxygen atom. Preferable examples thereof include a substituted or unsubstituted methylene group, ethylene group, propylene group, and butylene group, an ethylene oxide group, a diethylene oxide group, a triethylene oxide group, a tetraethylene oxide group, a dipropylene oxide group, a tripropylene oxide group, and a tetrapropylene oxide group.

Further, L² preferably represents a straight chain, branched, or cyclic alkylene group, an aromatic group, or a group obtained by combining these groups. With regard to the group obtained by combining an alkylene group and an aromatic group, the alkylene group and the aromatic group may be bonded through an ether group, an ester group, an amido group, a urethane group, or a urea group. Above all, L² is preferably a group having a total number of carbon atoms of from 1 to 15, and is particularly preferably an unsubstituted group. Herein, the total number of carbon atoms of L² means a total number of carbon atoms contained in the substituted or unsubstituted divalent aliphatic or aromatic hydrocarbon group represented by L².

Specific examples thereof include a methylene group, an ethylene group, a propylene group, a butylene group, a phenylene group, these groups each of which is substituting with a methoxy group, a hydroxyl group, a chlorine atom, a bromine atom, a fluorine atom, or the like, and groups obtained by combining these groups.

In the cyano group-containing polymerizable polymer in the present invention, the unit represented by Formula (1) above is preferably a unit represented by the following Formula (3).

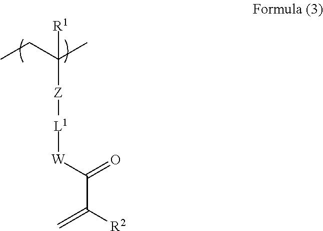

In Formula (3) above, each of R¹ and R² independently represents a hydrogen atom or a substituted or unsubstituted alkyl group; Z represents a single bond, a substituted or unsubstituted divalent aliphatic or aromatic hydrocarbon group, an ester group, an amido group, or an ether group; W represents an oxygen atom or NR (wherein R represents a hydrogen atom or an alkyl group, and preferably represents a hydrogen atom or an unsubstituted alkyl group having from 1 to 5 carbon atoms); and L¹ represents a substituted or unsubstituted divalent aliphatic or aromatic hydrocarbon group.

R¹ and R² in Formula (3) have the same definitions as R¹ and R² in Formula (1) above, respectively, and so are the preferable examples.

Z in Formula (3) has the same definition as Z in Formula (1) above, and so are the preferable examples.

Further, L¹ in Formula (3) has the same definition as L¹ in Formula (1) above, and so are the preferable examples.

In the cyano group-containing polymerizable polymer in the present invention, the unit represented by Formula (3) above is preferably a unit represented by the following Formula (4).

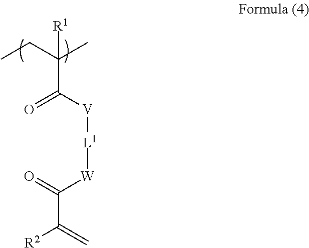

In Formula (4), each of R¹ and R² independently represents a hydrogen atom or a substituted or unsubstituted alkyl group; each of V and W independently represents an oxygen atom or NR (wherein R represents a hydrogen atom or an alkyl group, and preferably represents a hydrogen atom or an unsubstituted alkyl group having from 1 to 5 carbon atoms); and L¹ represents a substituted or unsubstituted divalent aliphatic or aromatic hydrocarbon group.

R¹ and R² in Formula (4) have the same definitions as R¹ and R² in Formula (1) above, respectively, and so are the preferable examples.

L¹ in Formula (4) has the same definition as L¹ in Formula (1) above, and so are the preferable examples.

In Formula (3) and Formula (4) above, W preferably represents an oxygen atom.

Further, in Formula (3) and Formula (4) above, L¹ preferably represents an unsubstituted alkylene group or a divalent aliphatic or aromatic hydrocarbon group having a urethane bond or a urea bond, and more preferably represents a divalent aliphatic or aromatic hydrocarbon group having a urethane bond. In particular, a group having a total number of carbon atoms of from 1 to 9 is preferable.

In the cyano group-containing polymerizable polymer in the present invention, the unit represented by Formula (2) above is preferably a unit represented by the following Formula (5).

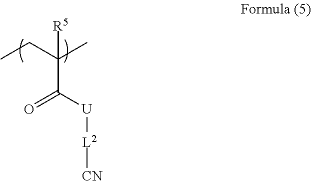

In Formula (5) above, R⁵ represents a hydrogen atom or a substituted or unsubstituted alkyl group; U represents an oxygen atom or NR′ (wherein R¹ represents a hydrogen atom or an alkyl group, and preferably represents a hydrogen atom or an unsubstituted alkyl group having from 1 to 5 carbon atoms); and L² represents a substituted or unsubstituted divalent aliphatic or aromatic hydrocarbon group.

R⁵ in Formula (5) has the same definition as R¹ and R² in Formula (1) above, and preferably represents a hydrogen atom.

Further, L² in Formula (5) has the same definition as L² in Formula (1) above, and preferably represents a straight chain, branched, or cyclic alkylene group, an aromatic group, or a group obtained by combining these groups.

Particularly, in Formula (5), the linkage site to the cyano group in L² is preferably a divalent aliphatic or aromatic hydrocarbon group having a straight chain, branched, or cyclic alkylene group. In particular, it is preferable that the above divalent aliphatic or aromatic hydrocarbon group has a total number of carbon atoms of from 1 to 10.

Furthermore, as another preferable embodiment, the linkage site to the cyano group in L² in Formula (5) is preferably a divalent aliphatic or aromatic hydrocarbon group having an aromatic group. In particular, it is preferable that the above divalent aliphatic or aromatic hydrocarbon group has a total number of carbon atoms of from 6 to 15.

In the cyano group-containing polymerizable polymer in the present invention, it is preferable that the ratios of the polymerizable group-containing unit and the cyano group-containing unit relative to the total amount of copolymerization components are within the following ranges, respectively.

Namely, the polymerizable group-containing unit is preferably contained in an amount of from 5 mol % to 50 mol % with respect to the total amount of copolymerization components, and more preferably in an amount of from 5 mol % to 40 mol %. When the amount is 5 mol % or less, the reactivity (curability or polymerizing ability) may be deteriorated. When the amount is more than 50 mol %, gelling may easily occur during the synthesis, resulting in difficulty in the synthesis.

Further, the cyano group-containing unit is preferably contained in an amount of from 5 mol % to 95 mol % with respect to the total amount of copolymerization components, and more preferably in an amount of from 10 mol % to 95 mol %, from the viewpoint of adsorptivity to the plating catalyst.

The cyano group-containing polymerizable polymer in the present invention may contain an additional unit other than the cyano group-containing unit and the polymerizable group-containing unit. As a monomer used for forming the additional unit, any monomer may be used as long as the monomer does not impair the effects of the invention.

Specific examples of the monomer which may be used for the formation of the additional unit include monomers capable of forming a main chain skeleton such as an acrylic resin skeleton, a styrene resin skeleton, a phenol resin (phenol-formaldehyde resin) skeleton, a melamine resin (polycondensate of melamine and formaldehyde) skeleton, a urea resin (polycondensate of urea and formaldehyde) skeleton, a polyester resin skeleton, a polyurethane skeleton, a polyimide skeleton, a polyolefin skeleton, a polycycloolefin skeleton, a polystyrene skeleton, a polyacrylic skeleton, an ABS resin (polymer of acrylonitrile, butadiene, and styrene) skeleton, a polyamide skeleton, a polyacetal skeleton, a polycarbonate skeleton, a polyphenylene ether skeleton, a polyphenylene sulfide skeleton, a polysulfone skeleton, a polyether sulfone skeleton, a polyarylate skeleton, a polyether ether ketone skeleton, or a polyamideimide skeleton.

Further, these main chain skeletons may be a main chain skeleton of the cyano group-containing unit or the polymerizable group-containing unit.

However, in a case in which a polymerizable group is reacted with a polymer and introduced into the polymer as described above, when the polymerizable group is difficult to be introduced in a proportion of 100%, a small amount of a reactive portion may remain, and there is a possibility that the remaining reactive portion works as a third unit.

Specifically, in a case in which the polymer main chain is formed by radical polymerization, examples of a monomer which may be used include unsubstituted (meth)acrylic acid esters such as ethyl(meth)acrylate, butyl(meth)acrylate, hexyl (meth)acrylate, 2-ethylhexyl(meth)acrylate, cyclohexyl(meth)acrylate, benzyl(meth)acrylate, and stearyl(meth)acrylate; halogen-substituted (meth)acrylic acid esters such as 2,2,2-trifluoroethyl(meth)acrylate, 3,3,3-trifluoropropyl(meth)acrylate, and 2-chloroethyl(meth)acrylate; ammonium group-substituted (meth)acrylic acid esters such as 2-(meth)acryloyloxyethyl trimethylammonium chloride; (meth)acrylamides such as butyl(meth)acrylamide, isopropyl(meth)acrylamide, octyl(meth)acrylamide, and dimethyl(meth)acrylamide; styrenes such as styrene, vinylbenzoic acid, and p-vinylbenzyl ammonium chloride; vinyl compounds such as N-vinylcarbazole, vinyl acetate, N-vinylacetamide, and N-vinylcaprolactam; and others such as dimethylaminoethyl (meth)acrylate, diethylaminoethyl(meth)acrylate, 2-ethylthio-ethyl(meth)acrylate, (meth)acrylic acid, and 2-hydroxyethyl(meth)acrylate.

Macromomers obtained from the above-described monomers may be used as well.

In a case in which the polymer main chain is formed by cationic polymerization, examples of a monomer which may be used include vinyl ethers and vinyl esters such as ethyl vinyl ether, butyl vinyl ether, isobutyl vinyl ether, cyclohexyl vinyl ether, ethylene glycol vinyl ether, di(ethylene glycol) vinyl ether, 1,4-butanediol vinyl ether, 2-chloroethyl vinyl ether, 2-ethylhexyl vinyl ether, vinyl acetate, 2-vinyloxy tetrahydropyran, vinyl benzoate, and vinyl butyrate; styrenes such as styrene, p-chlorostyrene, and p-methoxystyrene; and terminal ethylenes such as allyl alcohol and 4-hydroxy-l-butene.

The weight average molecular weight of the cyano group-containing polymerizable polymer in the present invention is preferably from 1,000 to 700,000, and more preferably from 2,000 to 200,000. Particularly, from the viewpoint of polymerization sensitivity, it is preferable that the weight average molecular weight of the cyano group-containing polymerizable polymer in the present invention is 20,000 or more.

Further, regarding the degree of polymerization of the cyano group-containing polymerizable polymer in the present invention, it is preferable to use a polymer of 10-mer or more, and more preferably a polymer of 20-mer or more. Furthermore, it is preferable to use a polymer of 7,000-mer or less, more preferably a polymer of 3,000-mer or less, even more preferably a polymer of 2,000-mer or less, and particularly preferably a polymer of 1,000-mer or less.

The preferable ranges of molecular weight and degree of polymerization as described herein are preferably applied as well to the polymers having a polymerizable group and an interactive group used in the present invention, other than the cyano group-containing polymerizable polymer.

Solvent

The solvent used for the formation of the polymer adhesive layer 20 according to the present invention is not particularly limited as long as the solvent can dissolve the specific polymer precursor which is the main component of the composition. A surfactant may be further added to the solvent.

Examples of the solvent, which may be used, include alcohol-based solvents such as methanol, ethanol, propanol, ethylene glycol, glycerin, and propylene glycol monomethyl ether; acids such as acetic acid; ketone-based solvents such as acetone, methyl ethyl ketone, and cyclohexanone; amide-based solvents such as formamide, dimethylacetamide, and N-methylpyrrolidone; nitrile-based solvents such as acetonitrile and propionitrile; ester-based solvents such as methyl acetate and ethyl acetate; carbonate-based solvents such as dimethyl carbonate and diethyl carbonate.

Among them, in the case of preparing a composition including a cyano group-containing polymerizable polymer, amide-based solvents, ketone-based solvents, nitrile-based solvents, and carbonate-based solvents are preferable. Specifically, acetone, dimethylformamide, dimethylacetamide, methyl ethyl ketone, cyclohexanone, acetonitrile, propionitrile, N-methylpyrrolidone, and dimethyl carbonate are preferable.

In the case of coating the composition including the cyano group-containing polymerizable polymer, a solvent having a boiling point of from 50° C. to 150° C. is preferable from the viewpoint of ease of handling. These solvents may be used alone or in a combination by mixing them.

Further, in the present invention, in the case of coating the composition including the compound having a polymerizable group and an interactive group on the insulating resin layer 16 or on the adhesion auxiliary layer 18, which is disposed over the surface of the core substrate 10, a solvent having a solvent absorption coefficient of the substrate or the insulating resin layer or the adhesion auxiliary layer of from 5% to 25% may be selected. The solvent absorption coefficient can be determined from the change in mass when the substrate or a base material formed thereon the insulating resin layer or the adhesion auxiliary layer is immersed in the solvent and pulled up after 1,000 minutes.

Furthermore, in the case of coating the composition including the compound having a polymerizable group and an interactive group on the substrate or on the insulating resin layer or the adhesion auxiliary layer, a solvent having a swelling ratio of the substrate or the insulating resin layer or the adhesion auxiliary layer of from 10% to 45% may also be selected. The swelling ratio can be determined from the change in thickness when the substrate or a base material formed thereon the insulating resin layer or the adhesion auxiliary layer is immersed in the solvent and pulled up after 1,000 minutes.

The surfactant that may be added to the solvent as needed may be any surfactant as long as the surfactant is soluble in the solvent. Examples of such a surfactant include anionic surfactants such as sodium n-dodecylbenzenesulfonate; cationic surfactants such as n-dodecyltrimethylammonium chloride; and nonionic surfactants such as polyoxyethylene nonyl phenol ether (for example, commercially available product: EMULGEN 910 (trade name), manufactured by Kao Corporation, or the like), polyoxyethylene sorbitan monolaurate (for example, commercially available product: TWEEN 20 (trade name), or the like), and polyoxyethylene lauryl ether.

As necessary, a plasticizer can also be added. Examples of the plasticizer which can be used include general plasticizers such as esters of phthalic acid (dimethyl ester, diethyl ester, dibutyl ester, di-2-ethylhexyl ester, di-normal-octyl ester, diisononyl ester, dinonyl ester, diisodecyl ester, or butylbenzyl ester), esters of adipic acid (dioctyl ester or diisononyl ester), dioctyl azelate, esters of sebacic acid (dibutyl ester or dioctyl ester), tricresyl phosphate, tributyl acetylcitrate, epoxidized soybean oil, trioctyl trimellitate, chlorinated paraffin, and solvents having a high boiling point such as dimethylacetamide and N-methylpyrrolidone.

A polymerization inhibitor can also be added to the composition including the compound having a polymerizable group and an interactive group, as necessary. Examples of the polymerization inhibitor that can be used include hydroquinones such as hydroquinone, di-tertiary-butyl hydroquinone, and 2,5-bis(1,1,3,3-tetramethylbutyl)hydroquinone; phenols such as p-methoxyphenol and phenol; benzoquinones; free radicals such as TEMPO (2,2,6,6-tetramethyl-1-piperidinyloxy free radical) and 4-hydroxy TEMPO; phenothiazines; nitrosoamines such as N-nitrosophenyl hydroxyamine and an aluminum salt thereof; and catechols.

Further, a curing agent and/or a curing accelerator can be added, as necessary, to the composition including the compound having a polymerizable group and an interactive group, in order to accelerate curing of the insulating resin layer or the adhesion auxiliary layer. For example, in a case in which an epoxy compound is contained in the polymerization initiation layer, examples of the curing agent and/or curing accelerator include:, as polyaddition type, aliphatic polyamine, alicyclic polyamine, aromatic polyamine, polyamide, acid anhydride, phenol, phenol novolac, polymercaptane, and a compound having two or more active hydrogen atoms; and as catalyst type, aliphatic tertiary amine, aromatic tertiary amine, an imidazole compound, and a Lewis acid complex.

Examples of the curing agents and/or curing accelerators that start curing due to heat, light, humidity, pressure, acid, base, or the like include diethylenetriamine, triethylenetetramine, tetraethylenepentamine, diethylaminopropylamine, polyamideamine, menthenediamine, isophorone diamine, N-aminoethylpiperazine, 3,9-bis(3-aminopropyl)-2,4,8,10-tetraoxyspiro(5,5)undecane adducts, bis(4-amino-3-methylcyclohexyl)methane, bis(4-aminocyclohexyl)methane, m-xylenediamine, diaminodiphenylmethane, m-phenylenediamine, diaminodiphenylsulfone, dicyandiamide, adipic acid dihydrazide, phthalic anhydride, tetrahydrophthalic anhydride, hexahydrophthalic anhydride, methyltetrahydrophthalic anhydride, methylhexahydrophthalic anhydride, methyl nadic anhydride, dodecylsuccinic anhydride, chlorendic anhydride, pyromellitic anhydride, benzophenonetetracarboxylic anhydride, ethylene glycol bis(anhydrotrimate), methylcyclohexenetetracarboxylic anhydride, trimellitic anhydride, polyazelaic anhydride, phenol novolac, xylylene novolac, bis-A novolac, triphenylmethane novolac, biphenyl novolac, dicyclopentadiene phenol novolac, terpene phenol novolac, polymercaptan, polysulfide, 2,4,6-tris(dimethylaminomethyl)phenol, 2,4,6-tris(dimethylaminomethyl)phenol-tri-2-ethylhexyl acid salts, benzyldimethylamine, 2-(dimethylaminomethyl)phenol, 2-methylimidazole, 2-ethyl-4-methylimidazole, 2-undecylimidazole, 2-heptadecylimidazole, 2-phenylimidazole, 1-benzyl-2-methylimidazole, 1-cyanoethyl-2-methylimidazole, 2,4-diamino-6-(2-methylimidazolyl-(1))-ethyl S-triazine, BF₃ monoethylamine complexes, Lewis acid complexes, organic acid hydrazide, diaminomaleonitrile, melamine derivatives, imidazole derivatives, polyamine salts, amineimide compounds, aromatic diazonium salts, diallyliodonium salts, triallylsulfonium salts, triallylselenium salts, and ketimine compounds.

The above curing agent and/or curing accelerator is preferably added at an amount of from about 0% by mass to about 50% by mass of a non-volatile component remaining after the solvent has been removed, from the viewpoints of coating property of a solution, adhesion to the substrate or the plated film, and the like. Further, the curing agent and/or curing accelerator may also be added to the adhesion auxiliary layer 18. In this case, it is preferable that the total of the amount of the curing agent and/or curing accelerator added to the adhesion auxiliary layer 18 and the amount of the curing agent and/or curing accelerator added to the polymer adhesion layer 20 satisfies the above range.

Furthermore, a flame retardant, (for example, a phosphorus-based flame retardant), a diluent or a thixotropic agent, a pigment, an antifoamer, a leveling agent, a coupling agent, or the like may further be added. These additives may be added to the adhesion auxiliary layer 18, if necessary.

In the present invention, in the case of contacting the composition for forming the polymer adhesion layer in the form of a liquid as it is, the formation of the polymer adhesion layer 20 may be arbitrary performed, but in a case in which the composition layer is formed by a coating method, the coating amount is preferably from 0.1 g/m² to 10 g/m², and particularly preferably from 0.5 g/m² to 5 g/m² in terms of the solid content, from the viewpoints of achieving sufficient interactivity with a plating catalyst or a precursor thereof, and obtaining a uniform coating film.

In this manner, the laminated body 22 according to the present invention including: a core substrate 10; and an insulating resin layer 16, an adhesion auxiliary layer 18 formed as desired, and a polymer adhesive layer 20, which are formed over the surface of the core substrate 10, may be obtained (see, FIG. 1A). This laminated body is useful for the formation of a receiving layer for a plating metal. Accordingly, the laminated body in the present invention is useful for forming a plated film (a second wiring), that exhibits satisfactory adhesion, over the core substrate 10. In FIG. 1A, the insulating resin layer 16, the adhesion auxiliary layer 18, and the polymer adhesive layer 20 are provided on both sides of the core substrate 10, however these layers may be provided only on one side of the core substrate 10.

Process (2) of Applying Energy in a Patterned Manner to a Region Outside of a Via Connection Portion on the Surface of the Laminated Body, to Form a Pattern-Shaped Polymer Adhesive Layer Bonded to the Insulating Resin Layer, at the Light-Exposed Region

In the laminated body 22 thus formed, the region where a via is to be formed is a region where a wiring 14 on the core substrate 10 has been formed.

Here, as shown in FIG. 1B, a mask 24 is provided so that the region where a via is to be formed (via connection portion) is made to be a light shielding portion, and then energy is applied.

In the region where energy is applied, the specific polymer precursor contained in the polymer adhesive layer 20 forms a specific polymer, which directly bonds to the adhesion auxiliary layer 18, by the application of energy, and thus, a polymer adhesive layer 20 which directly bonds to the adhesion auxiliary layer 18 is formed in a patterned manner, and this region becomes a plating catalyst receiving layer. The specific polymer precursor which exists at the non-exposed area is removed through development by an appropriate method (FIG. 1C).

The process (2) is preferably a process of forming, on the adhesion auxiliary layer 18, a polymer adhesive layer 20 in a pattered manner by directly and chemically bonding a polymer having a functional group, that interacts with a plating catalyst or a precursor thereof to form a coordination bond, and a polymerizable group.

In the process(2), a polymer precursor having a polymerizable group and an interactive group is bought into contact with the top of the adhesion auxiliary layer 18, and then energy is applied through the mask 24, thereby directly and chemically bonding the specific polymer precursor to the region where the mask 24 is not provided.

In what follows, the case of using a graft polymerization method as an example of a method of directly and chemically bonding the specific polymer precursor to the adhesion auxiliary layer or the insulating resin layer is described. As the graft polymerization method to be applied to the present invention, any method publicly known through literatures may be used. For example, a photo-graft polymerization method and a plasma irradiation graft polymerization method as surface graft polymerization methods are described in “Shin-Kobunshi Jikkengaku 10 (New Polymer Experimentation 10)”, edited by the Polymer Science of Japan, 1994, published by Kyoritsu Publishing, page 135. Further, a method of irradiation graft polymerization with radiation such as γ-rays, electron beams, or the like is described in Kyuchaku Gijutsu Binran (Adsorption Technology Handbook), edited by Takeuchi, published by NTS Inc. on February 1999, page 203 and page 695. Among these methods, it is preferable to form a resin composition layer by using a photo-graft polymerization method, particularly preferably a photo-graft polymerization method using UV light, from the viewpoint of generating a larger amount of graft polymer.

Specifically, the methods described in JP-A Nos. 63-92658, 10-296895, and 11-119413 may be used as a method of photo-graft polymerization.

As a method of forming the polymer adhesive layer of the present invention and directly bonding the polymer adhesive layer to the adhesion auxiliary layer or the insulating resin layer, other than the above grafting method, a method of attaching a reactive functional group such as a trialkoxysilyl group, an isocyanate group, an amino group, a hydroxyl group, a carboxyl group, or the like to a terminal of a polymer compound chain, and bonding the reactive functional group with a functional group present at the surface of the substrate by a coupling reaction, or the like may also be used.

In the present invention, in the case of using a graft polymerization method in which an active species is provided at the surface of the adhesion auxiliary layer 18, and forming a graft polymer using the active species as the starting point, it is preferable that the adhesion auxiliary layer 18 contains a polymerization initiator at the time of the formation of the graft polymer. In such an embodiment, active points may be efficiently generated, and thus a larger amount of graft polymer can be formed.

In this case, the adhesion auxiliary layer 18 may contain a combination of a polymer compound and a polymerization initiator, a combination of a polymerizable compound and a polymerization initiator, or a compound having a functional group capable of initiating polymerization.

The polymerization initiator used herein is described, for example, in paragraphs [0043] to [0044] in JP-A No. 2007-154306. The polymerization initiator may be selected as appropriate from know polymerization initiators represented by these polymerization initiators and used depending on the purpose. Among them, since the use of photopolymerization is preferable from the viewpoint of production suitability, it is preferable to use a photopolymerization initiator.

The photopolymerization initiator is not particularly limited as long as the initiator is active with respect to the actinic rays to be irradiated and is capable of initiating graft polymerization. For example, a radical polymerization initiator, an anionic polymerization initiator, a cationic polymerization initiator, or the like can be used. A radical polymerization initiator is preferable from the viewpoint of reactivity.

The content of the polymerization initiator in the adhesion auxiliary layer containing the polymerization initiator (hereinafter, referred to as “polymerization initiation layer”) is preferably from 0.1% by mass to 70% by mass, and particularly preferably from 1% by mass to 40% by mass, in terms of the solid content.

Further, as the polymerization initiator, a photo-cationic polymerization initiator or a photo-radical polymerization initiator may also be used.

According to the present invention, in the case of forming an adhesion auxiliary layer 18 containing a polymerization initiator, the adhesion auxiliary layer containing a polymerization initiator is formed by disposing the composition for forming the adhesion auxiliary layer 18 on the surface of the insulating resin layer 16 provided on the core substrate 10 by means of coating or the like, and removing the solvent to form a film, as described above. In this process, it is preferable to cure the film by heating and/or photoirradiation. In particular, when preliminary curing of the film is conducted by photoirradiation, after drying the film by heating, curing of the polymerizable compound may proceed at a certain extent in advance, and the situation in which, after grafting is achieved, the whole polymerization initiation layer falls off may be effectively prevented, which is preferable.

In regard to the heating temperature and time, those conditions under which the solvent used for coating can sufficiently dry up may be selected. In view of production suitability, it is preferable to select a temperature of 100° C. or lower and a drying time of 30 minutes or less, and it is more preferable to select heating conditions within the range of a drying temperature of from 40° C. to 80° C. and a drying time of 10 minutes or less.

The photoirradiation that is carried out as desired after drying by heating may be performed by using a light source which is used for grafting reaction described below. In the succeeding grafting reaction, it is preferable that the photoirradiation is conducted in such a manner that the polymerizable compound present in the polymerization initiation layer is not completely radically polymerized, even if the polymerizable compound is partially radically polymerized, from the viewpoint of not inhibiting the formation of the bond between the active point in the polymerization initiation layer and the graft chain by applying energy. The time for photoirradiation may vary depending on the intensity of the light source, but is generally preferably within 30 minutes. The preliminary curing may be conducted, for example, in such a manner that the remaining rate of the film after washing with a solvent is 10% or less and the remaining rate of the polymerization initiator after completing the . preliminary curing is 1% or more.

As another embodiment of generating a graft polymer, a method of utilizing a coupling reaction between a functional group that exists at the surface of the adhesion auxiliary layer 18 and a reactive functional group contained in a terminal or side chain of the specific polymer precursor, as described above, or the like may be used.

In the present invention, an embodiment is preferable, in which a functional group (interactive group) that forms an interaction with a plating catalyst or a precursor thereof is present at the top of the adhesion auxiliary layer 18, and a polymer adhesive layer 20 including a polymer that is directly and chemically bonded to the polymerization initiation layer is formed. In this embodiment, a specific polymer precursor having a polymerizable group and an interactive group is brought into contact with the top of the adhesion auxiliary layer 18, and then energy is applied through a mask 24, thereby directly and chemically bonding the specific polymer only to the region where the energy is applied.

In the layer formation of the polymer adhesive layer 20, after a layer containing a compound having a polymerizable group and an interactive group is formed, and at an interval between the coating and drying, the resulting layer may be left for 0.5 hours to 2 hours at a temperature of from 20° C. to 40° C., to remove a remaining solvent.

Application of Energy

As a method of applying energy for forming a polymer adhesive layer 20, for example, radiation irradiation such as exposure may be used. Specifically, for example, light irradiation with a UV lamp or visible light may be used. Examples of the light source include a mercury lamp, a metal halide lamp, a xenon lamp, a chemical lamp, and a carbon arc lamp. Examples of the radiation rays include electron beams, X-rays, ion beams, and far-infrared rays. Further, g-line rays, i-line rays, deep-UV light, high-density energy beams (laser beams) are also applicable.

Specific embodiments of energy application in which a mask 24 is not used include patterned heat using a thermal recording head or the like, scan exposure using infrared laser beam, and further, as a favorable method, high-light intensity flash exposure using a xenon discharge lamp or the like, or exposure with an infrared lamp.

The time for energy application may vary depending on the intended amount of graft polymer formation or the type of light source, but is typically from 10 seconds to 5 hours.

When the application of energy is performed by exposure, the exposure power is preferably 10 to 5,000 mJ/cm², more preferably 50 to 3,000 mJ/cm², from the viewpoints of readily promoting the graft polymerization and suppressing the decomposition of formed graft polymer.

When a specific polymer having an average molecular weight of 20,000 or more and a polymerization degree of 200-mer or more is used, graft polymerization may readily progress even when exposure is performed at low energy. Therefore, the decomposition of formed graft polymer may be further suppressed.

The formed polymer adhesive layer 20 may be subjected to washing with a highly alkaline solution, provided that not more than 50% of the polymerizable group site decomposes after placing the layer in an alkaline solution of pH 12 and stirring it for 1 hour, for example.

Alternatively, it is also possible to remove the uncured and unreacted specific polymer precursor, by washing using the above-described solvent capable of dissolving the uncured and unreacted specific polymer precursor ar a mixed solvent including the above solvent.

In this way, a pattern including a portion where the specific polymer is present and a portion where the specific polymer precursor is removed is formed. Note that, in the case of the present invention, application of energy is not carried out to the portion that becomes a via-portion. Therefore, a specific polymer pattern (a pattern-shaped polymer adhesive layer) in a state in which the polymer precursor at the via-portion is removed is formed.

By the process (2) as described above, a patterned polymer adhesive layer (plating catalyst receiving layer) 20 including a graft polymer having an interactive group may be formed on the laminated body 22.

As for the polymer compound included in the patterned polymer adhesive layer obtained in this process, it is preferable to use a polymer having a cyano group as the functional group that forms an interaction with a plating catalyst or a precursor thereof, for example, the cyano group-containing synthetic polymer described above. As described above, the cyano group has high polarity and high absorption ability to the plating catalyst or the like, but does not have water absorbing property and hydrophilicity as high as those of a dissociative polar group (hydrophilic group). Accordingly, the polymer adhesive layer 20 including the graft polymer having a cyano group as described above may be a layer having low water absorbing property and high hydrophobicity.

Process (3) of Applying a Plating Catalyst or a Precursor Thereof to the Patterned Polymer Adhesive Layer, and Carrying out a First Electroless Plating, to Form a Second Metal Wiring on the Surface of the Patterned Polymer Adhesive Layer

In process (3), a plating catalyst or a precursor thereof is applied to the polymer adhesive layer 20 formed through the above process (1) and process (2). In this process, the interactive group (preferably, a cyano group) possessed by the polymer that constitutes the polymer adhesive layer 20 sticks (adheres) the applied plating catalyst or precursor thereof, corresponding to a function thereof.

Here, the plating catalyst and precursor thereof includes those having a function as a catalyst or electrode for plating in an electroless plating process. Accordingly, the plating catalyst or precursor thereof is determined depending on the kind of plating in the succeeding plating process.

Herein, the plating catalyst or precursor thereof used in this process is preferably an electroless plating catalyst or a precursor thereof.

Electroless Plating Catalyst

In the invention, the electroless plating catalyst may be any compound as long as it serves as an active core during performing electroless plating. Examples thereof include metals having a catalytic ability for a self-catalytic reduction reaction, and specific examples include Pd, Ag, Cu, Ni, Al, Fe, Co and the like. Among them, those capable of multidentate coordination are preferred. From the viewpoints of the number of types of a functional group capable of coordination and superiority in the catalytic ability, Ag and Pd are particularly preferred.

This electroless plating catalyst may be used in the form of a metal colloid. In general, a metal colloid may be produced by reducing metal ions in a solution containing a charged surfactant or a charged protective agent. The electrical charge of the metal colloid may be controlled by the surfactant or protective agent used herein.

Electroless Plating Catalyst Precursor

The electroless plating catalyst precursor used in this step is not particularly limited and may be any compound as long as it may serve as an electroless plating catalyst by a chemical reaction. In general, metal ions of the metals mentioned above as the electroless plating catalyst are used. A metal ion that serves as an electroless plating catalyst precursor becomes a zero-valent metal that serves as an electroless plating catalyst through a reduction reaction. The metal ion as an electroless plating catalyst precursor may be converted to a zero-valent metal to obtain an electroless plating catalyst by performing a separate reduction reaction, after being applied to the resin composition layer and prior to immersing in an electroless plating bath, or may be converted to a metal (electroless plating catalyst) while being immersed in an electroless plating bath by means of a reducing agent contained in the electroless plating bath.

Practically, the metal ion as an electroless plating catalyst precursor is applied onto the resin composition layer by utilizing a metal salt. The metal salt to be used is not particularly limited as long as it can be dissolved in an appropriate solvent to dissociate into a metal ion and a base (anion). Specific examples thereof include M(NO₃)ₙ, MClₙ, M_{2/n}(SO₄), and M_{3/n}(PO₄) (where M represents an n-valent metal atom). A dissociated species of the above-mentioned metal salt may be suitably used as the metal ion. Specific examples of the metal ion include an Ag ion, a Cu ion, an Al ion, a Ni ion, a Co ion, a Fe ion, and a Pd ion. Among them, those capable of multidentate coordination are preferred. From the viewpoints of the number of types of a functional group capable of coordination and the catalytic ability, a Ag ion or a Pd ion is particularly preferred.

One preferable example of the electroless plating catalyst or precursor thereof used in the present invention is a palladium compound. The palladium compound acts as a plating catalyst (palladium) or a precursor thereof (palladium ion), which serves as an active nucleus at the time of the plating treatment and plays a role for the deposition of metals. The palladium compound is not particularly limited as long as the compound contains palladium and works as a nucleus at the time of the plating treatment. Examples thereof include, but are not particularly limited to, palladium (II) salts, palladium (0) complexes, and palladium colloid.

Examples of the palladium salts include palladium acetate, palladium chloride, palladium nitrate, palladium bromide, palladium carbonate, palladium sulfate, bis(benzonitrile)dichloropalladium (II), bis(acetonitrile)dichloropalladium (II), and bis(ethylenediamine)palladium (II) chloride. Among them, from the viewpoints of easiness in handling and solubility, palladium nitrate, palladium acetate, palladium sulfate, and bis(acetonitrile)dichloropalladium (II) are preferable.

Examples of the palladium complexes include tetrakis[tri(phenyl)phosphine] palladium complex and tris(benzylideneacetone)dipalladium complex.

The palladium colloid includes particles formed from palladium (0). Although the size of the particle is not particularly limited, the particle size is preferably from 5 nm to 300 nm, and more preferably from 10 nm to 100 nm, from the viewpoint of stability in a liquid. The palladium colloid may contain other metal, as necessary. Examples of the other metal include tin. Examples of the palladium colloid include tin-palladium colloid. The palladium colloid may be synthesized according to a known method, or a commercially available product may be used. For example, the palladium colloid can be prepared by reducing a palladium ion in a solution containing a charged surfactant or a charged protective agent.

Other Catalysts

As a catalyst that is used to directly perform electroplating without performing electroless plating, a zero-valent metal may be used. Examples of the zero-valent metal include Pd, Ag, Cu, Ni, Al, Fe and Co. Among them, those capable of multidentate coordination are preferred. From the viewpoints of the adsorbability (attachability) to the interactive group (such as a cyano group) and the superiority in catalytic ability, Pd, Ag and Cu are particularly preferred.

A method of applying a metal that serves as an electroless plating catalyst or a metal salt that serves as an electroless plating precursor to a resin composition layer may be a method in which a dispersion liquid obtained by dispersing a metal in a proper dispersion medium or a solution which is obtained by dissolving a metal salt in a proper solvent and contains a dissociated metal ion is prepared, and the resulting dispersion liquid or solution is coated on the resin composition layer, or a substrate formed thereon the resin composition layer is immersed in the resulting dispersion liquid or solution.

Further, in a case in which a surface graft polymerization method is used in the process (2), a method in which an electroless plating catalyst or a precursor thereof is added to the composition, which contains a compound having a polymerizable group and an interactive group (a cyano group), and is to be brought into contact with the top of the adhesion auxiliary layer 18, may be used. When the composition, that contains a compound having a polymerizable group and an interactive group (a cyano group), and an electroless plating catalyst or a precursor thereof, is brought into contact with the top of the adhesion auxiliary layer 18 and a surface graft polymerization method is used, a polymer adhesive layer 20 containing a polymer, which has an interactive group (a cyano group) and is directly and chemically bonded to the adhesion auxiliary layer 18, and the plating catalyst or precursor thereof may be formed. When the above method is used, the process (2) and a part of the process (3) in the present invention may be carried out at the same time.

Note that, in a case in which a polymer adhesive layer 20 is formed on both sides of the core substrate 10 as in the case shown in FIG. 1, the above immersion method is preferably used in order to bring the electroless plating catalyst or precursor thereof into contact with the polymer adhesive layers 20 formed on the both sides at the same time.

Organic Solvent and Water

The plating catalyst or the precursor as described above is applied to the layer to be subjected to plating, in the form of a dispersion liquid or a solution (a catalyst liquid), as described above.

An organic solvent or water is used in the catalyst liquid according to the present invention.

When an organic solvent is contained in the catalyst liquid as described above, the permeability of the plating catalyst or the precursor into the layer to be subjected to plating may be improved, and the plating catalyst or precursor thereof may be effectively adhered to the interactive group.

Water may also be used in the catalyst liquid according to the present invention. It is preferable that the water used herein does not contain impurities, and from such a point of view, it is preferable to use RO (reverse osmosis) water, deionized water, distilled water, purified water, or the like, and it is particularly preferable to use deionized water or distilled water.

The organic solvent used for preparing the plating catalyst liquid is not particularly limited as long as the organic solvent is a solvent capable of permeating into the layer to be subjected to plating. Specific examples of the organic solvent, which may be used, include acetone, methyl acetoacetate, ethyl acetoacetate, ethylene glycol diacetate, cyclohexanone, acetylacetone, acetophenone, 2-(1-cyclohexenyl), propylene glycol diacetate, triacetin, diethylene glycol diacetate, dioxane, N-methylpyrrolidone, dimethylcarbonate, and dimethyl cellosolve.

Other examples of the organic solvent include diacetone alcohol, γ-butyrolactone, methanol, ethanol, isopropyl alcohol, normal-propyl alcohol, propylene glycol monomethyl ether, methyl cellosolve, ethyl cellosolve, ethylene glycol tertiary-butyl ether, tetrahydrofuran, and 1,4-dioxane.

Particularly, from the viewpoints of mutual solubility with the plating catalyst or precursor thereof and permeability into the layer to be subjected to plating, a water-soluble organic solvent is preferable, and specifically, acetone, dimethylcarbonate, dimethyl cellosolve, triethylene glycol monomethyl ether, diethylene glycol dimethyl ether, and diethylene glycol diethyl ether are preferable.

Further, examples of other solvents, which can be used in combination, include diacetone alcohol, γ-butyrolactone, methanol, ethanol, isopropyl alcohol, normal-propyl alcohol, propylene glycol monomethyl ether, methyl cellosolve, ethyl cellosolve, ethylene glycol tertiary-butyl ether, tetrahydrofuran, 1,4-dioxane, and n-methyl-2-pyrrolidone. A non-water-soluble solvent may be mixed with the solvent as mentioned above, at an amount up to the solubility limit to water. For example, dimethyl carbonate may be mixed with water at an amount of up to 12.5%; triacetin may be mixed with water at an amount of up to 7.2%; and cyclohexanone may be mixed with water at an amount of up to 9%.

The content of the solvent is preferably in the range of from 0.5 to 40% by mass, more preferably from 5 to 30% by mass, and particularly preferably from 5 to 20% by mass, relative to the total quantity of the plating catalyst liquid.

The plating catalyst liquid of the invention may contain other additives in accordance with purposes, in addition to the plating catalyst or the precursor thereof and water which is a main solvent, to such an extent that the effect of the invention is not impaired.

Examples of the additive include swelling agents (organic compound such as ketones, aldehydes, ethers, esters, or the like), and surfactants (anionic surfactants, cationic surfactants, amphoteric surfactants, nonionic surfactants, low-molecular surfactants, high-molecular surfactants, or the like).

As mentioned above, by contacting the electroless plating catalyst or the precursor thereof to the resin composition layer, the electroless plating catalyst or the precursor thereof may be adsorbed to the interactive group (such as a cyano group) in the resin composition layer by means of an intermolecular force such as van der Waal's force, or a coordination bond by lone-pair electrons.

In view of sufficiently performing the adsorption, the concentration of metal in a dispersion, solution or composition, or the concentration of metal ion in a solution, is preferably from 0.001 to 50 mass %, more preferably from 0.005 to 30 mass %. The time for contacting is preferably from about 30 seconds to about 24 hours, more preferably from about 1 minute to about 1 hour.

Through a preliminary stage of the step (3), an interaction between the interactive group (such as a cyano group) in the resin composition layer and the plating catalyst or the precursor thereof may be achieved.

Thereafter, plating (first electroless plating) is performed with respect to the polymer adhesive layer 20 to which the electroless plating catalyst or precursor thereof has been applied, thereby forming a plated film 26 on the surface of the polymer adhesive layer 20 formed in a patterned manner (FIG. 1D). The plated film 26 thus formed functions as a second wiring and has excellent electric conductivity and excellent adhesion.

The type of plating which is performed in this process is electroless plating, but it is possible to further perform electroplating as required.

Especially, it is preferable to perform electroless plating from the viewpoint of improving the formation of a hybrid structure that occurs in the polymer adhesive layer 20, or enhancing the adhesiveness. Further, in order to obtain a plating layer having a desired thickness, it is more preferable to perform electroplating after the electroless plating.

Hereinafter, the plating that is suitably carried out in this step will be described.

Electroless Plating

Electroless plating refers to an operation of precipitating a metal by means of a chemical reaction, using a solution in which ions of the metal to be precipitated is dissolved.

The electroless plating in this step is carried out by, for example, washing the substrate to which the electroless plating catalyst has been applied, with water to remove excess electroless plating catalyst (metal), and then immersing the substrate in an electroless plating bath. A generally known electroless plating bath may be used as the electroless plating bath.

When a substrate to which an electroless plating catalyst precursor has been provided is immersed in the electroless plating bath, while the electroless plating catalyst precursor has been adsorbed or impregnated in the resin composition layer, the substrate is washed with water to remove excess precursor (metal salt or the like), and then is immersed in the electroless plating bath. In this case, reduction of the plating catalyst precursor and the subsequent electroless plating are carried out in the electroless plating bath. In this case, a generally known electroless plating bath may be also used as the electroless plating bath.

In a different embodiment from the above, the reduction of the electroless plating catalyst precursor may be carried out in a separate process, prior to the electroless plating, by preparing a catalyst activating solution (reducing solution). The catalyst activating solution is a solution dissolving therein a reducing agent capable of reducing the electroless plating catalyst precursor (mainly a metal ion) to a zero-valent metal, and the concentration of the reducing agent is generally in a range of from 0.1% by mass to 50% by mass, and is preferably in a range of from 1% to 30% by mass. Examples of the reducing agent that may be used include boron-based reducing agents such as sodium borohydride and dimethylamineborane, and reducing agents such as formaldehyde and hypophosphorous acid.

The composition of the electroless plating bath generally includes, as main components in addition to a solvent, a metal ion for the plating (1), a reducing agent (2), and an additive (3) that enhances the stability of the metal ion (stabilizer). The electroless plating bath may further contain, in addition to the above components, a known additive such as a stabilizer for the electroless plating bath.

The solvent used in the plating bath preferably includes an organic solvent that exhibits high affinity to the resin composition layer having low water absorbability and is highly hydrophobic, for example, the resin composition layer that satisfies at least one of the aforementioned requirements (1) to (4). The type or the content of the organic solvent may be determined in accordance with the properties of the resin composition layer. In particular, as the resin composition layer has a high degree of saturated water absorption rate at the requirement (1), the content of the organic solvent is preferably lowered.

Specifically, when the saturated water absorption rate at the requirement (1) is from 0.01 to 0.5% by mass, the content of the organic solvent in the entire solvent in the plating bath is preferably from 20 to 80% by mass; when the saturated water absorption rate at the requirement (1) is from 0.5 to 5% by mass, the content of the organic solvent in the entire solvent in the plating bath is preferably from 10 to 80% by mass; when the saturated water absorption rate at the requirement (I) is from 5 to 10% by mass, the content of the organic solvent in the entire solvent in the plating bath is preferably from 0 to 60% by mass; and when the saturated water absorption rate at the requirement (1) is from 10 to 20% by mass, the content of the organic solvent in the entire solvent in the plating bath is preferably from 0 to 45% by mass.

The organic solvent used in the plating bath needs to be miscible with water, and from that standpoint, ketones such as acetone, and alcohols such as methanol, ethanol and isopropanol are preferably used.

Examples of the metal used in the electroless plating bath include copper, tin, lead, nickel, gold, palladium and rhodium, and from the viewpoint of electrical conductivity, copper and gold are preferred.

The optimal reducing agent and additive may be selected in combination with the metal to be used. For example, the electroless plating bath of copper contains CuSO₄ as a copper salt, HCOH as a reducing agent, and a chelating agent that serves as a stabilizer of copper ions such as EDTA or Rochelle salt, and trialkanolamine or the like. The electroless plating bath of CoNiP contains cobalt sulfate or nickel sulfate as a metal salt, sodium hypophosphite as a reducing agent, and sodium malonate, sodium malate or sodium succinate as a complexing agent. The electroless plating bath of palladium contains (Pd(NH₃)₄)Cl₂ as a metal ion, NH₃ or H₂NNH₂ as a reducing agent, and EDTA as a stabilizer. These plating baths may also contain other components than the above-described components.

The thickness of the plated film formed by electroless plating may be controlled by adjusting the concentration of the metal ion in the plating bath, the immersion time in the plating bath, the temperature of the plating bath, or the like. From the viewpoint of electroconductivity, the thickness of the plated film is preferably 0.2 μm or more, and more preferably 0.5 μm or more.

The immersion time in the plating bath is preferably about 1 minute to about 6 hours, and more preferably about 1 minute to about 3 hours.

By observing the cross-section with a scanning electron microscope (SEM), it may be confirmed that microparticles of the electroless plating catalyst or the plated metal are dispersed in the resin composition layer at high density, and that the plated metal is precipitated on the resin composition layer. Since the interface between the substrate and the plated film is in a hybrid state of the polymer and the microparticles, favorable adhesiveness may be achieved even when the interface between the substrate (organic component) and the inorganic substance (catalyst metal or plated metal) is flat and smooth (for example, the roughness is 500 nm or less).

Electroplating

In this step, if the plating catalyst or the precursor thereof applied during step (3) has a function as an electrode, electroplating may be performed to the resin composition layer to which the catalyst or the precursor thereof has been applied.

It is also possible to perform electroplating after performing the above-described electroless plating, by using a plated film that has been formed in the electroless plating as an electrode. In this case, a metal film having a desired thickness may be easily formed on an electroless plated film that serves as a base having excellent adhesiveness to the substrate. Therefore, it is possible to form a metal film having a desired thickness by performing electroplating after the electroless plating, which has the advantage that the metal film of the invention can be used in various applications.

The method of performing electroplating according to the invention may be a conventionally known method. Examples of the metal that may be used in the electroplating include copper, chromium, lead, nickel, gold, silver, tin, and zinc. From the viewpoint of electrical conductivity, copper, gold and silver are preferred, while copper is more preferred.

The film thickness of the metal film obtained by electroplating may vary depending on the usage and may be controlled by adjusting the concentration of the metal contained in the plating bath, the current density, or the like.

However, as described below, in a case in which a pattern is formed by a semiadditive method using the present invention, the portion other than the portion where the wiring is formed is to be removed afterwards by etching. Accordingly, electroplating may be not necessarily performed in the process (3) of applying a plating catalyst or a precursor thereof to the patterned polymer adhesive layer, and carrying out a first electroless plating, to form a metal film on the surface of the patterned polymer adhesive layer. In the present invention, electroless plating is not performed at the portion where via is intended to be formed, and thus a metal film pattern is formed in a manner such that a metal does not exist at the portion where via is intended to be formed.

In the present invention, when the metal or metal salt derived from the plating catalyst or plating catalyst precursor described above and/or the metal that has been deposited in the polymer adhesive layer 20 by electroless plating form (forms) a fractal fine structure in the layer, the adhesion between the metal film (second metal wiring) 26 and the polymer adhesive layer 20 can be further improved.

Regarding the amount of the metal that is present in the polymer adhesive layer 20, in a case in which the proportion of metal in a region from the outermost surface of the polymer adhesive layer 20 to a depth of 0.5 μm is from 5% by area to 50% by area, and the arithmetic average roughness Ra (JIS B0633-2001, which is incorporated by reference herein) of the interface between the polymer adhesive layer 20 and the metal is from 0.05 μm to 0.5 μm when a cross section of the substrate is photographed using a metallurgical microscope, a stronger adhesive force may be developed.

Process (4) of Forming a Via Using the Patterned Second Metal wiring as a Mask, and Subsequently Carrying Out a Desmear Treatment

A laminated substrate having two layers of wirings is obtained by going through the above processes of (1) to (3). Thereafter, in process (4), via 28 for electrically connecting the first wiring and the second wiring is formed.

The method of forming the via is not particularly limited, and examples thereof include a method using drilling processing, a method using chemical etching, a method of irradiating a laser, a method using plasma etching or the like. Among them, from the viewpoint of suitability to fine processing, a method of forming via by laser processing or the like is preferable.

In the formation of via, the patterned metal film (second metal wiring) 26 that has been formed in advance has a function as a mask, and further, the first wiring 14 functions as a stopper. Therefore, for example, in the laser processing, when via 28 reaches the first wiring, drilling is not conducted any more, so that via 28 in which the first wiring 14 becomes a bottom portion thereof is formed. Even if the masked portion is irradiated with a laser, via is not likely to be formed, and therefore, the laser positioning accuracy can be lowered. Namely, even in a case in which a laser having a relatively lower positioning accuracy is used, high positioning accuracy in via formation can be maintained. Furthermore, it is possible to make the process of via formation simple and easy, by utilizing the function of the metal film 26 (second metal wiring) as a mask, and by using a method of forming holes on the entire surface at once such as plasma etching or chemical etching.

Regarding the laser used in this process, any laser having an oscillation wavelength within a wavelength region of from the ultraviolet light region to the infrared light region may be used. It should be noted that the above ultraviolet light region refers to a wavelength region within a range of from 50 nm to 400 nm, and the infrared light region refers to a wavelength region within a range of from 750 nm to 1 mm. Examples of the laser which can be used include an ultraviolet laser and carbon dioxide laser.

The emission wavelength region of the ultraviolet laser is generally from 180 nm to 380 nm, preferably from 200 nm to 380 nm, and more preferably from 300 nm to 380 nm. Examples of lasers for obtaining the ultraviolet laser include gas lasers such as Ar, N₂, ArF, KrF, XeCl, XeF, He—Cd, and He—Ne lasers; solid-state lasers such as YAG (Yttrium Aluminum Garnet), NdYAG, Nd glass, and alexandrite lasers; and dye lasers using a dye dissolved in an organic solvent. Particularly, a YAG laser and an NdYAG laser are preferable, since they can oscillate high output energy and have high durability, and laser devices thereof can be maintained with low-cost. As the oscillation wavelength of the ultraviolet ray region, harmonics of these lasers are preferably used. The laser harmonics can be obtained by, for example, oscillating a laser beam (fundamental wave) having a wavelength of 1.06 μm using a YAG laser or the like, transmitting the laser beam through two nonlinear crystals (LBO crystals) which are laid in parallel with each other with a predetermined distance therebetween in the direction of the light path to generate an SHG (Second Harmonic Generation) light having a wavelength of 0.53 μm, and then converting the light into a THG light (ultraviolet ray) having a wavelength of 0.355 μm. Examples of a device used for obtaining such harmonics include a laser processing apparatus disclosed in, for example, JP-A No. 11-342485. Lasers can be irradiated continuously or intermittently. However, it is preferable to irradiate intermittently with a single pulse in view of preventing the occurrence of clacks.

The irradiation number of times (number of shots) in the single pulse irradiation is generally from 5 times to 500 times, and preferably from 10 times to 100 times. As the irradiation number of times increases, the processing time gets longer and clacks tends to occur easily. The pulse period is generally from 3 kHz to 8 kHz, and preferably from 4 kHz to 5 kHz. A carbon dioxide laser is a molecule laser in which the efficiency of conversion of electric power into laser beam is 10% or more and the oscillation wavelength is 10.6 μm, and which can generate large output as large as several tens of kW. Generally, a carbon dioxide laser has energy of from about 20 mJ to about 40 mJ, and irradiation of short pulse of about 10⁻⁸ seconds to about 10⁻⁴ seconds is carried out. The number of shots of pulse needed for via formation is generally from about 5 shots to about 1000 shots.

Via 28 to be formed becomes a through hole which is used for the formation of electrical connection between the first wiring 14 and the second wiring 26 (FIG. 1E).

The ratio of the inside diameter (d1) of the via bottom portion relative to the inside diameter (d0) of the hole entrance (surface) portion (hole diameter ratio: d1/d0×100 [%]) is generally 40% or higher, preferably 50% or higher, and more preferably 65% or higher. Further, d0 is preferably in a range of from 10 μm to 250 μm, and more preferably in a range of from 20 μm to 80 μm. When the hole-diameter ratio is great, electric connection failure is less likely to occur, and high reliability may be achieved.

After the formation of via, a desmear treatment is performed to remove smear which remains in the formed via 28. The desmear treatment is carried out by a method of roughening the inside of via by a dry method and/or a wet method. Examples of the dry roughening method include mechanical polishing such as buffing or sand blasting, and plasma etching. Examples of the wet roughening method include a chemical treatment such as a method using an oxidant such as permanganate, dichromate, ozone, hydrogen peroxide/sulfuric acid, or nitric acid, a strong base, or a resin swelling solvent. From the viewpoint that the process is easy and simple, a chemical treatment using permanganate or the like is preferable.

The desmear treatment method may be carried out as appropriate by a known method. For example, a method of immersing the substance to be treated in a swelling bath including 20% by volume of a commercially available product MLB211 (trade name, manufactured by Rohm and Haas Electronic Materials K.K.) and 10% by volume of CUPOSIT Z (trade name, manufactured by Rohm and Haas Electronic Materials K.K) at a temperature of from 60° C. to 85° C. for 1 minute to 15 minutes, then immersing it in an etching bath including 10% by volume of MLB213A (trade name, manufactured by Rohm and Haas Electronic Materials K.K.) and 15% by volume of MLB213B (trade name, manufactured by Rohm and Haas Electronic Materials K.K.) at a temperature of from 55° C. to 85° C. for 2 minutes to 15 minutes, and then immersing it in a neutralization bath including 20% by volume of MLB216-2 (trade name, manufactured by Rohm and Haas Electronic Materials K.K.) at a temperature of from 35° C. to 55° C. for 2 minutes to 10 minutes may be used.

By performing the desmear treatment, the region where a metal film is to be formed, namely, the surfaces of the first wiring 14 and the second wiring 26, are not affected by the chemicals and surface smoothness thereof may be maintained, whereas in the insulating resin exposed portion at the inner face of the via, smear is removed and the surface thereof is roughened. Accordingly, the advantage such as improvement in affinity and adhesion to the metal material provided by the electroless plating or metal filling treatment in the electric connection processing, which is subsequently carried out as required, may be realized.

According to the method of the present invention, it is confirmed that, even after the desmear treatment, the surface of each of the first wiring 14 and the second wiring 26 maintains its smoothness such that Ra is from 0.05 μm to 0:3 μm, and Ra of the inner face of the via becomes 0.8 μm or more. The ratio of Ra of the wiring portion/Ra of the inner face of the via becomes from 0.05 to 0.5. By conventional wiring forming methods, Ra of the inner face of the via is 0.8 μm or more, which is almost the same as that obtained by this method, but Ra of the wiring portion is 1.0 μm or more. Even in a case in which a desmear treatment is not conducted, Ra of the wiring portion is 0.8 μm or more, and the ratio of Ra of the wiring portion/Ra of the inner face of the via becomes from about 0.8 to about 5. Also from this point of view, it is understood that the present invention is excellent. Note that, the surface roughness Ra used herein is an arithmetic average roughness Ra, and a value measured by the method described in ISO 4288 (1996, which is incorporated herein by reference) is adopted.

Representative examples of the desmear treatment include a treatment including an etching process at a temperature of 80° C. for 10 minutes using a sodium permanganate based etchant, a neutralization process at a temperature of 40° C. for 5 minutes using a sulfuric acid based neutralizing liquid, and the like.

In place of the desmear treatment using chemicals, a treatment including washing with a solvent that dissolves or swells the insulating resin layer 16 may be carried out.

Note that, it is preferable to carry out a conditioning treatment or a catalyst applying treatment, which is generally performed before performing the plating treatment described below, to the inside of the via, for the purpose of ensuring better adhesion.

It is understood that a laminated substrate having two layers of wirings can be easily formed by going through the above (1) process to (4) process, without going through complicated processes, which have been generally conducted conventionally, such as processes of forming a copper clad insulating resin layer on a core substrate, patterning the copper foil using a resist to form a second wiring, and then peeling off the resist, thereby forming a via.

Process (5) of Carrying Out a Second Electroless Plating Treatment or an Electrically Conductive Paste Filling Treatment to the Inside of the Formed Via, to Electrically Connect the Metal Wiring on the Surface of the First Wiring Substrate and the Second metal wiring that has been Formed on the Surface of the Patterned Polymer Adhesive Layer

By disposing an electrically conductive material on the face inside of the via 28 that is formed through the process (1) to process (4), the first wiring 14 on the core substrate and the second metal wiring 26 can be electrically connected.

The electrically conductive material may be disposed on the face inside of the via 28 by an electroless plating treatment or an electrically conductive paste filling treatment to the inside of the formed via 28. Above all, from the viewpoint of strength of junction, a method of utilizing electroless plating is preferable, since copper which is the same material as the wiring material can be used.

Herein, the second electroless plating treatment can be carried out by substantially the same method as the method for the first electroless plating treatment applied to the formation of the second metal wiring 26.

FIG. 1F is a model diagram showing that the metal film 30 for electrically connecting the first wiring 14 and the second wiring 26 is formed by electroless plating. When an electroless plating method is used, the plated film (metal film) 30 is formed not only on the inner face of via 28, but also on the surfaces of the first wiring 14 and the second wiring 26, regarding the wiring as the plating receiving layer.

The electrically conductive paste to be used for the electrically conductive paste filling treatment is not particularly limited, and the kind and the filling amount can be selected as appropriate depending on the purposes. Examples of the electrically conductive paste which can be used in the present invention include silver paste containing silver nano particles.

In this way, a multilayer wiring substrate in which two layers of wirings are electrically connected can be obtained.

The obtained multilayer wiring substrate having two layers of wirings may be used as a substrate to be a core for forming an additional wiring thereon, so as to be applicable to packaging. As the method of laminating an additional wiring on the multilayer wiring substrate obtained by the production method of the present invention, a known semiadditive method, subtractive method, or the like can be used.

Hereinafter, a representative method for forming an additional wiring by using the multilayer wiring substrate obtained by the production method of the present invention is described. The following process (6) to process (9) can be carried out for further forming a wiring on the surface of the second wiring 26.

Process (6) of Forming a Plating Resist Layer on the Surface of the Second Metal wiring that has been Formed on the Surface of the Patterned Polymer Adhesive Layer

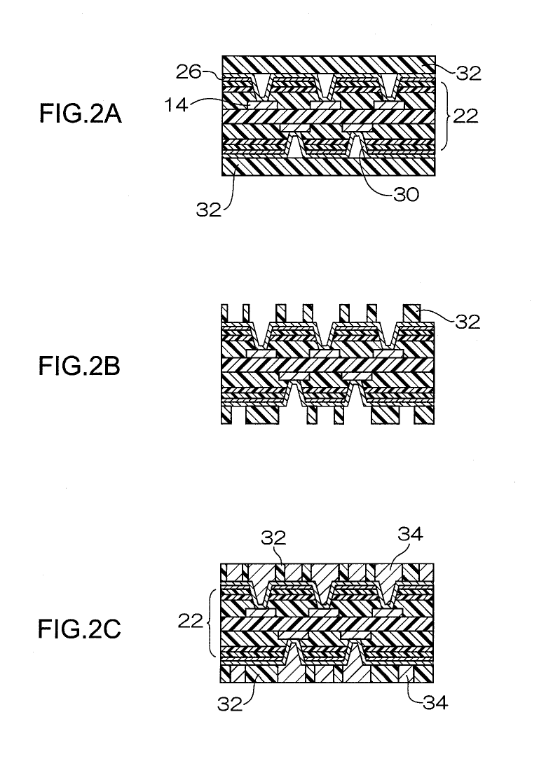

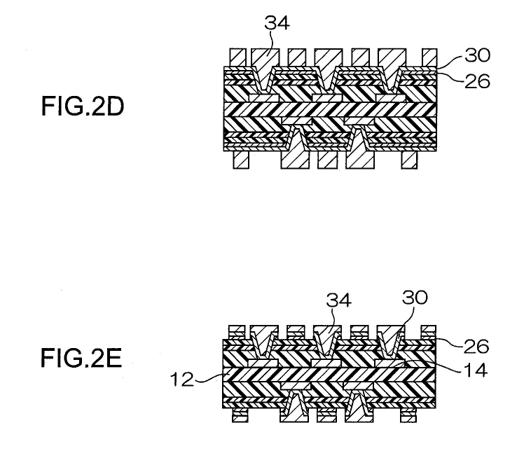

In this process, a plating resist layer 32 is formed over the surface of the second wiring 26 (FIG. 2A). The plating resist layer can be formed by a known method, a generally used dry film resist, solder resist, or the like may be used, and a dry film resist is preferably used. Any material can be used for the dry film resist, and a negative type material, a positive type material, a liquid material, or a film-shaped material can be used.

The thickness of the plating resist layer 32 is selected according to the thickness of the additional wiring to be formed, but generally, the thickness is preferably from 5 μm to 200 μm. When the thickness is less than 5 μm, the film is easily cut and is difficult to handle. It is preferable that the thickness is 200 μm or less, from the viewpoints of handling properties such as a property of satisfying the bending resistance.

Process (7) of Patterning the Plating Resist Layer

Next, the plating resist layer 32 formed is subjected to pattern exposure and development, thereby performing patterning, to form a pattern such that a resist is not present at the same region as the region of the wiring pattern (metal pattern) to be formed and a resist layer 32 is present only at the region where the metal pattern is not formed (FIG. 2B).

As the method of forming a pattern of a dry film resist, any methods used for the production of print wiring substrates are applicable.

Process (8) of Carrying Out Electroplating, by Utilizing the Plating Resist Layer to Form a Wiring Pattern

Then, electroplating is carried out by using the patterned plating resist layer 32 as a mask, to form a patterned metal layer 34 at the region where the plating resist layer 32 is not formed. As a result, an additional wiring pattern 34 is formed (FIG. 2C).

The electroplating can be carried out in a manner substantially the same as that described in the method of forming the second wiring 26.

The film thickness of the wiring pattern 34 to be formed may be selected depending on the purpose of the wiring, but generally, it is preferable that the film thickness is in a range of from 0.3 μm to 3 μm.

Process (9) of After the Formation of the Wiring Pattern, Removing the Plating Resist Layer Corresponding to a Non-Wiring Pattern Portion, which has been Used to Conduct Electrical Connection in the Electroplating

After the wiring pattern 34 is formed, the plating resist layer 32 corresponding to the non wiring region is removed. In this way, as shown in FIG. 2D, a patterned plated metal layer (a wiring pattern) 34 is formed only at the region where the plating resist layer 32 has not been formed. Note that, as shown in FIG. 2D, the formed additional wiring patterns 34 are electrically connected with each other by the second wiring 26 which is the lower layer and the metal layer 30 formed on the surface thereof by electroless plating. Therefore, as needs arise, when quick etching is carried out after removing the dry film resist pattern and unnecessary regions in the metal films 26 and 30 are removed in a patterned manner, the formation of the additional wiring pattern 34 is completed, and a multilayer wiring substrate can be obtained (FIG. 2E). As the etching method, any methods used for the production of print wiring substrates are applicable, and any of wet etching or dry etching may be used, but from the viewpoint of workability, wet etching is preferable. As the etchant, for example, an aqueous solution of cupric chloride, ferric chloride, or the like can be used.

As to the dry film resist, etchant, and the like used in the process (6) to process (9), materials substantially the same as those used in known subtractive methods can be used.

According to the production method of the present invention, wirings which exhibit excellent adhesion to the substrate and which have their excellent sectional shape in the form of rectangle can be easily formed through a simple process. Further, since the surface of each of the wirings is smooth and the sectional shape of the wirings is rectangle, the multilayer wiring substrate obtained by the production method of the present invention has excellent electric characteristics.

In the above exemplary embodiment, representative processes are explained, but as long as the method of the invention includes the process (1) to process (4), other processes may be arbitrary included.

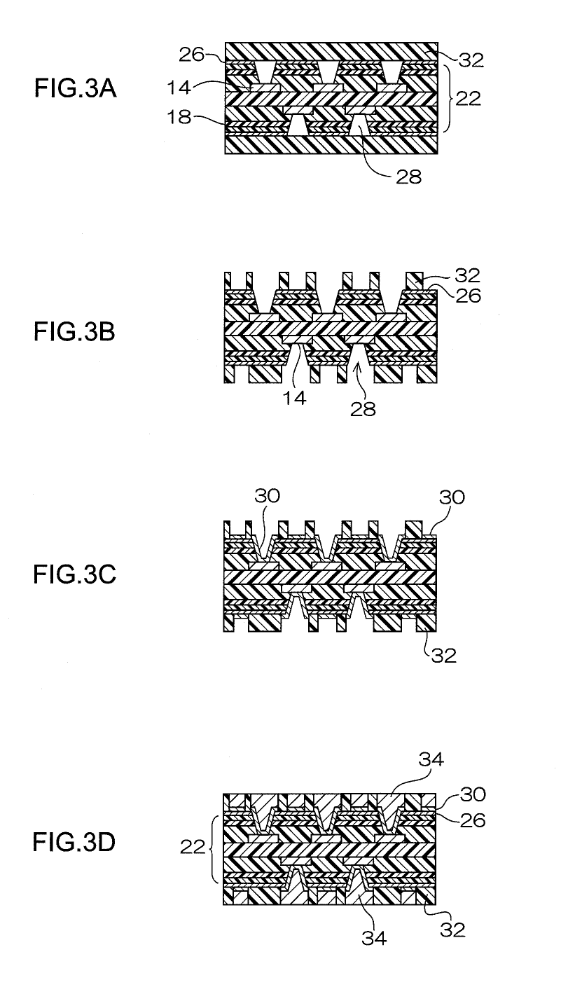

For example, immediately after process (4), process (6) is carried out to form a plating resist layer, without carrying out the electroless plating treatment in process (5) (FIG. 3A), and then process (7) is carried out to perform patterning of the plating resist layer (FIG. 3B), and then an electroless plating treatment is carried out in a manner substantially similar to that in process (5) to form a metal layer 30 (FIG. 3C), and then electroplating in process (8) is carried out using the electroless plated film 30 as a starting point, whereby an additional wiring pattern 34 can be formed (FIG. 3D). In this case, when process (9) is subsequently carried out, a multilayer wiring substrate having a rectangular sectional shape and fine wiring pattern can be produced.

In the production method of the present invention, a typically exemplified embodiment resides in that “a laminated body having an insulating resin layer and a polymer adhesive layer, on a surface of a first wiring substrate, in which the polymer adhesive layer contains a polymer precursor having a functional group, that forms an interaction with a plating catalyst or a precursor thereof, and a polymerizable group” used in process (1)is used. By utilizing such a laminated body, the production of a multilayer wiring substrate may be easily carried out.

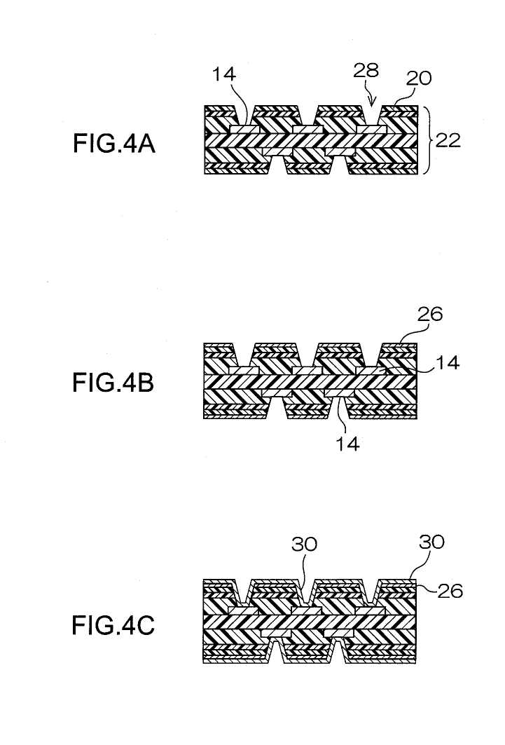

One example of other method of application of such a laminated body is a method of applying energy to the laminated body 22 obtained in process (1) to form a polymer adhesive layer 20 on the entire surface, and then forming a via 28 using a laser (FIG. 4A); carrying out the formation of the via 28 and patterning of the polymer adhesive layer 20 at the same time in such a manner, and then carrying out an electroless plating treatment to form a second wiring 26 on the surface of a patterned polymer adhesive layer 20 (FIG. 4B); carrying out a desmear treatment before or after the formation of the second wiring 26, and thereafter forming a metal film 30 to electrically connect the first wiring 14 and the second wiring 26 (FIG. 4C).

It is possible to produce a multilayer wiring substrate through carrying out the above process (6) to process (9) with respect to such a laminated body.

Furthermore, it is also possible to produce a multilayer wiring substrate by the following method. Namely, without performing the above patterning processes, energy is applied to the entire surface, and a metal layer is provided on the entire surface by plating, thereby obtaining a metal film clad laminated body having a form substantially the same as that in the case of generally used substrate in which a resin attached copper foil is adhered, and thereafter, via holes are made using a drill or a laser from the top of the metal film, and the succeeding processes which are substantially the same as the operations for producing a general build-up printed wiring board are carried out, thereby producing a multilayer wiring substrate.

Multilayer Wiring Substrate

The metal multilayer wiring substrate obtained by the production method of the present invention can be applied to various usage, for example, in semiconductor chips, various electrical wiring boards, FPC (Flexible Printed Circuit), COF (Chip on Film), TAB (Tape Automated Bonding), mother boards, package interposer substrate, or the like.

Above all, in the metal multilayer wiring substrate produced by the method of the present invention, a wiring exhibiting excellent adhesion to a smooth substrate can be easily formed, and satisfactory high frequency characteristics is achieved, and also excellent insulating reliability between wiring lines is obtained even if a fine high density wiring is formed.

### EXAMPLES

Hereinafter, the present invention will be further described in detail with reference to the following Examples, but the invention is not limited to the Examples. Unless otherwise noted, “%” and “part(s)” are in terms of mass.

### Example 1

Preparation of Core Substrate

An insulating resin layer 16 was formed by attaching, as an electrically insulating layer, an epoxy-based insulating film (GX-13, trade name, manufactured by Ajinomoto Fine-Techno Co., Inc., thickness: 45 μm), to a glass epoxy substrate 12 on which a first wiring 14 was previously formed by a vacuum laminator, and heating and pressing under the conditions of temperature: 100 to 110° C. and pressure: 0.2 MPa.

Formation of Adhesion Auxiliary Layer

A coating liquid was prepared by mixing 11.8 parts by mass of JER 806 (bisphenol F-type epoxy resin, trade name, manufactured by Japan Epoxy Resins Co., Ltd.), 4.8 parts by mass of LA 7052 (PHENOLITE, trade name, curing agent, manufactured by DIC Corporation), 21.7 parts by mass of YP 50-35 EK (phenoxy resin, trade name, manufactured by Tohto Kasei Co., Ltd.), 61.6 parts by mass of cyclohexanone, and 0.1 part by mass of 2-ethyl-4-methyl imidazole (curing promotor), and then filtering the mixture by a filter cloth (mesh: #200).

The coating liquid was applied onto the substrate by a spin coater (rotated at 300 rpm for 5 seconds and then at 1,500 rpm for 20 seconds) and then dried at 170° C. to cure, thereby obtaining substrate A1. The thickness of the cured adhesion auxiliary layer was 2.2 μm. The surface roughness (Ra) of substrate A1 was 0.5 μm (per 200 μm²).

Formation of Polymer Adhesive Layer

Preparation of Polymer A having Polymerizable Group and Interactive Group

Firstly, the polymer A having polymerizable group and interactive group was synthesized as described below.

35 g of N,N-dimethylacetoamide were placed into a 1000-ml three neck flask, and was heated to 75° C. under a nitrogen stream. Then, a solution of 35 g of N,N-dimethyladetoamide containing 6.60 g of 2-hydroxyethylacrylate (a product from Tokyo Chemical Industry Co., Ltd.), 28.4 g of 2-cyanoethylacrylate, and 0.62 g of V-601 (polymerization initiator, trade name, a product from Wako Pure Chemical Industries, Ltd.) was dropped into the flask over 2.5 hours. After completion of dropping, the mixture was heated to 80° C. and further stirred for 3 hours. Thereafter, the reaction solution was cooled to room temperature.

To the above reaction solution, 0.30 g of ditertiarybutyl hydroquinone, 0.28 g of dibutyltin dilaurate, 18.57 g of KARENZ AO1 (trade name, a product from Showa Denko K.K.) and 19 g of N,N-dimethylacetoamide were added and reacted at 55° C. for 4 hours. Thereafter, 3.6 g of methanol was added to the reaction solution and was further reacted for 1.5 hours. After completion of reaction, the reaction solution was subjected to reprecipitation with a mixture of ethyl acetate:hexane (1:1) to recover a solid. 32 g of polymer A having a polymerizable group and an interactive group (weight average molecular weight: 62,000) were thus obtained.

Preparation of Coating Liquid (Photosensitive Resin Composition for Plating 1)

To an acetonitrile solution containing 7% of polymer A having polymerizable group and interactive group, a synthetic rubber (NIPOL 1041, trade name, a product from Zeon Corporation) was added at an amount of 20 parts by mass with respect to 100 parts by mass of the polymer A. Thus, a coating liquid of photosensitive resin composition for plating 1 was prepared.

Formation of Graft Polymer

The thus-prepared coating liquid was coated onto the adhesion auxiliary layer of substrate A1 by a spin coater (rotated at 300 rpm for 5 seconds and then at 750 rpm for 20 seconds), and then dried at 80° C. for 30 minutes.

After drying, irradiation was conducted through a quartz mask using a UV exposure device (type: UVF-502S, lamp: UXM-501MD, manufactured by San-ei Electric Co., Ltd.) for 100 seconds to form a patterned graft polymer on a surface of the adhesion auxiliary layer 18 provided on the core substrate 10. The irradiation power as measured by a UV integrated light intensity meter (UIT 150 with a light-receiving sensor UVD-S254, manufactured by Ushio Lighting, Inc.) was 10 mW/cm². The integrated exposure amount was 1,000 mJ.

Thereafter, substrate A1 with a graft polymer formed thereon was immersed in acetonitrile for 5 minutes while stirring, and then was washed with distilled water. A laminated body 22 having a patterned polymer adhesive layer 20 formed thereon was thus obtained. The thickness of the polymer adhesive layer 20 was 0.6 μm.

Measurement of Physical Properties of Polymer Adhesive Layer 20

The physical properties of the obtained polymer adhesive layer 20 were measured in accordance with the aforementioned method. As a result, the surface contact angle after dropping 5 μL of distilled water onto the polymer adhesive layer and leaving the same to stand for 15 seconds in an environment of 25° C-50% relative humidity was 60°, indicating that the polymer adhesive layer had a hydrophobic surface.

Application of Plating Catalyst

The laminated body 22 was immersed in a 0.05% by mass acetone solution of palladium nitrate for 30 minutes, and then washed with acetone and distilled water, respectively for a period of from 1 minute to 2 minutes.

First Electroless Plating

The laminated body 22 to which a plating catalyst had been applied was subjected to electroless plating with the electroless plating solution having the following composition, by utilizing a thin film electroless deposition method of copper (THROUGH-COPPER PGT, trade name, manufactured by C. Uyemura & Co., Ltd.), at 26° C. for 30 minutes. Thus, a laminated substrate having a metal film 26 on a surface of the laminated body 22 was obtained as shown in FIG. 1D. The thickness of the obtained electroless copper plated film was 0.5 μm.

The order of prepared liquids and the law materials in the electroless plating solution are as follows.

| | |
|---|---|
| Distilled water | approx. 60% by volume |
| PGT-A | 9.0% by volume |
| PGT-B | 6.0% by volume |
| PGT-C | 3.5% by volume |
| Formaldehyde solution* | 2.3% by volume |

Finally, the total amount of electroless plating solution was adjusted at a
liquid level with distilled water to 100% by volume.
*The formaldehyde solution herein used is a product from Wako Pure Chemical Industries, Ltd. (special grade).

Formation of Via

Using a UV-YAG laser, and adjusting the number of shots to be within the range of from 200 to 300 at a frequency of 5000 Hz and the pulse energy to be within the range of from 0.05 mJ to 0.12 mJ, vias having a via bottom diameter of 50 μm were formed.

Desmear Treatment

A desmear treatment for via was carried out by utilizing a desmear formula: including immersing the laminated body in a swelling bath including 20% by volume of MLB211 (trade name, manufactured by Rohm and Haas Electronic Materials K.K.) and 10% by volume of CUPOSIT Z (trade name) at a temperature of 70° C. for 7 minutes; then immersing it in an etching bath including 10% by volume of MLB213A (trade name, manufactured by Rohm and Haas Electronic Materials K.K.) and 15% by volume of MLB213B (trade name, manufactured by Rohm and Haas Electronic Materials K.K.) at a temperature of 80° C. for 10 minutes; and then immersing it in a neutralization bath including 20% by volume of MLB216-2 (trade name, manufactured by Rohm and Haas Electronic Materials K.K.) at a temperature of 45° C. for 7 minutes.

Second Electroless Plating

Subsequently, a second electroless copper plating was carried out under the same conditions as the conditions in the first electroless plating, whereby a metal film 30 was formed on the inner face of the via 28 and on the surface of the second wiring 26. The thickness of the obtained copper plated film on the inner face of via was 0.5 μm.

Formation of Plating Resist Layer for Electroplating and Patterning

The copper surface was washed with a hydrogen peroxide/sulfuric acid based soft etchant, and then a dry film resist (trade name: ALPHO NIT3025, manufactured by Nichigo-Morton Co., Ltd.) was laminated thereon at a temperature of 110° C. ±10° C. and at a pressure of 0.35 Mpa±0.05 Mpa. For printing of the circuit pattern, using a guide hole as a basis, pattern exposure was carried out by irradiation with ultraviolet rays at 120 mJ/cm² using an extra-high pressure mercury lamp, and then the dry film resist was developed using a 1% aqueous solution of sodium carbonate at 30° C. and at a spray pressure of 0.15 MPa, whereby a plating resist pattern was formed.

Electroplating

Electroplating was conducted for 20 minutes, using the electroless copper plated film 30 as the electric power supplying layer and using an electric copper plating bath having the composition described below under the condition of 3 A/dm². The thickness of the obtained electric copper plated film was 18 82 m.

Composition of Electric Plating Bath

| | | |
|---|---|---|
| Copper sulfate | 38 | g |
| Sulfuric acid | 95 | g |
| Hydrochloric acid | 1 | mL |
| Copper Gleam PCM | 3 | mL |
| (trade name, manufactured by Meltex, Inc.) | | |
| Water | 500 | g |

Peeling of Resist and Etching

By using a 5% by mass aqueous solution of sodium hydroxide as the resist peeling liquid and applying the resist peeling liquid to the surface of the electroless copper plated film at 80° C. and at a spray pressure of 0.2 MPa, the plating resist pattern was subjected to a peeling and removing treatment. Thereafter, the copper used as a background electrically conductive layer of the non-circuit pattern portion was removed by using a hydrogen peroxide/sulfuric acid based soft etchant.

Furthermore, according to needs, the wiring formation from the formation of the insulating resin layer was repeated to produce a desired multilayer wiring substrate. At the end, a solder resist was formed, and gold plating finishing was performed, to obtain a multilayer wiring substrate.

Evaluation of Multilayer Wiring Substrate

The fine wiring thus formed was observed using COLOR 3D LASER MICROSCOPE VK-9700 (trade name, manufactured by Keyence Corporation), and it was confirmed that a copper fine wiring having a thickness of 18 μm was formed without any defects. Further, the electric connection with a wiring substrate having the first wiring was checked, and it was confirmed that the connection was good. Furthermore, fine wiring formability was checked by observing the region where the wiring was formed, using the same COLOR 3D LASER MICROSCOPE VK-9700 (trade name, manufactured by Keyence Corporation), and it was confirmed that, until the line/space reached 10 μm/10 μm, wiring lines adjacent to each other did not connect each other, and wiring lines having excellent linearity with a uniform width were formed. At the same time, the wiring form was observed, and it was revealed that the shape of the edge portion of the wiring was a straight line.

Further, each of the surface roughness (Ra) of the via-portion and the second wiring portion was measured by a tracer method based on ISO 4288. The surface roughness (Ra) of the via-portion was measured after the desmear treatment. Concerning the surface roughness (Ra) of the second wiring portion, the surface roughness (Ra) of the portion where the metal had been removed by a method such as etching or the like, i.e., Ra of the surface of the patterned polymer adhesive layer on the side of the second metal wiring, was measured. As a result, it was revealed that Ra of the via-portion was 0.62 μm, Ra of the second wiring portion was 0.05 μm, and the ratio of Ra of the second wiring portion to Ra of the inner face of the via-portion was 0.08. Furthermore, it was found out that peeling off, floating, or the like did not occur at the wiring portion.

### EXAMPLE 2

In order to produce a multilayer wiring substrate of an embodiment in which the inside of the via is filled with a metal by plating Preparation of a multilayer wiring substrate was conducted in a manner substantially similar to that in Example 1, except that the conditions of the above electroplating were changed to the following conditions.

Composition of Electroplating Bath

| | | |
|---|---|---|
| Copper (II) sulfate pentahydrate | 280 | g |
| Concentrated sulfuric acid | 35 | g |
| Hydrochloric acid | 0.15 | mL |
| CU-BRITE VF-II A (trade name, manufactured by | 28.56 | mL |
| Ebara Udylite Co., Ltd.) | | |
| CU-BRITE VF-II B (trade name, manufactured by | 1.46 | mL |
| Ebara Udylite Co., Ltd.) | | |
| Distilled water | 1400 | g |

Electroplating was conducted for 50 minutes under the condition of 2 A/dm². The thickness of the obtained electric copper plated film was 20 μm.

When plating was conducted under the above conditions, the inside of the via was filled with copper.

Evaluation of Multilayer Wiring Substrate

The fine wiring thus formed was evaluated in a manner substantially similar to that in Example 1, and it was confirmed that a copper fine wiring having a thickness of 18 μm was formed without any defects. Further, the electric connection with a wiring substrate having the first wiring was checked, and it was confirmed that the connection was good.

Furthermore, fine wiring formability was evaluated in a manner substantially similar to that described above, and it was confirmed that, until the line/space reached 10 μm/10 μm, wiring lines adjacent to each other did not connect each other, and wiring lines having excellent linearity with a uniform width were formed. At the same time, the wiring form was observed, and it was revealed that the shape of the edge portion of the wiring was a straight line.

### EXAMPLE 3

Preparation of a multilayer wiring substrate was conducted in a manner substantially similar to that in Example 1, except that, the conditions of the desmear treatment was changed in a manner such that the immersion in the etchant at a temperature of 80° C. for 10 minutes in Example 1 was changed to immersion in the etchant at a temperature of 75° C. for 5 minutes. Each Ra of the via-portion and the wiring portion was measured, and it was revealed that Ra of the via-portion was 0.39 μm, Ra of the second wiring portion was 0.08 μm, and the ratio of Ra of the second wiring portion to Ra of the inner face of the via-portion was 0.21. The formation of wiring could be conducted until the line/space reached 8 μm/8 μm, and when the wiring form was observed, it was revealed that the shape of the edge portion of the wiring was a straight line. Furthermore, it was found that peeling off, floating, or the like did not occur at the wiring portion.

### EXAMPLE 4

Preparation of a multilayer wiring substrate was conducted in a manner substantially similar to that in Example 1, except that an insulating resin film containing silica having an average particle diameter of 0.3 μm was used instead of using the insulating resin film, GX-13 (trade name), in Example 1. Each Ra of the via-portion and the second wiring portion was measured, and it was revealed that Ra of the via-portion was 0.25 μm, Ra of the second wiring portion was 0.11 μm, and the ratio of Ra of the second wiring portion to Ra of the inner face of the via-portion was 0.44. The formation of wiring could be conducted until the line/space reached 8 μm/8 μm, and when the wiring form was observed, it was revealed that the shape of the edge portion of the wiring was a straight line. Further, it was found out that peeling off, floating, or the like did not occur at the wiring portion.

### EXAMPLE 5

Preparation of a multilayer wiring substrate was conducted in a manner substantially similar to that in Example 1, except that the conditions of the desmear treatment was changed in a manner such that the immersion in the etchant at a temperature of 80° C. for 10 minutes in Example 1 was changed to immersion in the etchant at a temperature of 70° C. for 1 minute. Each Ra of the via-portion and the second wiring portion was measured, and it was revealed that Ra of the via-portion was 0.15 μm, Ra of the second wiring portion was 0.08 μm, and the ratio of Ra of the second wiring portion to Ra of the inner face of the via-portion was 0.53. The formation of wiring could be conducted until the line/space reached 8 μm/8 μm, and when the wiring form was observed, it was revealed that the shape of the edge portion of the wiring was a straight line. Further, it was found that peeling off, floating, or the like did not occur at the wiring portion. However, smear remained at the via-portion, and there was a portion where interlayer connection failure occurred when a multilayer wiring was formed.

### Comparative Example 1

Preparation of a multilayer wiring board was conducted in a manner substantially similar to that in Example 1, except that the adhesion auxiliary layer and the polymer adhesive layer in Example 1 were not formed on the insulating resin film, the via formation was conducted without performing the first electroless plating, and the processes subsequent to the desmear treatment were conducted, whereby the wiring formation was conducted in accordance with a general semiadditive method. Each Ra of the via-portion and the second wiring portion was measured, and it was revealed that Ra of the via-portion was 0.55 μm, Ra of the second wiring portion was 0.65 μm, and the ratio of Ra of the second wiring portion to Ra of the inner face of the via-portion was 1.18. Further, it was found that peeling off, floating, or the like did not occur at the wiring portion. However, a wiring having a line/space of 12 μm/12 μm or less could not be formed, and when the wiring form was observed, irregularities were seen at the edge portion of the wiring due to the influence of surface roughness.

### Comparative Example 2

Preparation of a multilayer wiring substrate was conducted in a manner substantially similar to that in Example 4, except that the adhesion auxiliary layer and the polymer adhesive layer in Example 4 were not formed on the insulating resin film, the via formation was conducted without performing the first electroless plating, and the processes subsequent to the desmear treatment were conducted, whereby the wiring formation was conducted in accordance with a general semiadditive method. Each Ra of the via-portion and the second wiring portion was measured, and it was revealed that Ra of the via-portion was 0.28 μm, Ra of the second wiring portion was 0.35 μm, and the ratio of Ra of the second wiring portion to Ra of the inner face of the via-portion was 1.25. A wiring having a line/space of 10 μm/10 μm or less could not be formed, and when the wiring form was observed, slight irregularities were seen at the edge portion of the wiring due to the influence of surface roughness. Further, there was a portion where peeling off, floating, or the like slightly occurred in the wiring portion.

All publications, patent applications, and technical standards mentioned in this specification are herein incorporated by reference to the same extent as if each individual publication, patent application, or technical standard was specifically and individually indicated to be incorporated by reference.

What is claimed is:

1. A method for producing a multilayer wiring substrate, the method comprising:
(1) forming a laminated body comprising an insulating resin layer and a polymer adhesive layer, on a surface of a first wiring substrate comprising a metal wiring thereon, in which the polymer adhesive layer comprises a polymer precursor comprising a functional group that forms an interaction with a plating catalyst or a precursor thereof, and a reactive group capable of forming a bond with an adjacent layer on the first wiring substrate side;
(2) applying energy in a patterned manner to a region outside of a via connection portion on the surface of the laminated body, to form a patterned polymer adhesive layer, in which the polymer precursor is bonded to the insulating resin layer, at the energy-applied region;
(3) applying a plating catalyst or a precursor thereof to the patterned polymer adhesive layer, and carrying out a first electroless plating treatment, to form a second metal wiring on the surface of the patterned polymer adhesive layer; and
(4) forming a via by utilizing the patterned second metal wiring as a mask, and subsequently carrying out a desmear treatment.

2. The method for producing a multilayer wiring substrate according to claim 1, wherein: the polymer precursor comprises a cyano group and a polymerizable group; an adhesion auxiliary layer is disposed between the insulating resin layer and the polymer adhesive layer; and the processes (3) and (4) are performed in a manner such that a ratio of Ra of the surface of the patterned polymer adhesive layer on the side of the second metal wiring to Ra of an inner face of the via is from 0.05 to 0.50.

3. The method for producing a multilayer wiring substrate according to claim 1, further comprising:
(5) carrying out a second electroless plating treatment or an electrically conductive paste filling treatment at the formed via portion, to electrically connect the metal wiring on the surface of the first wiring substrate and the second metal wiring that has been formed on the surface of the patterned polymer adhesive layer.

4. The method for producing a multilayer wiring substrate according to claim 3, further comprising:
(6) forming a plating resist layer on the surface of the second metal wiring that has been formed on the surface of the patterned polymer adhesive layer;
(7) patterning the plating resist layer;
(8) carrying out electroplating by utilizing the plating resist layer, to form a wiring pattern; and
(9) after the formation of the wiring pattern, removing the plating resist layer corresponding to a non-wiring pattern portion, which has been used to conduct electrical connection in the electroplating.

5. The method for producing a multilayer wiring substrate according to claim 1, wherein the laminated body further comprising:
an adhesion auxiliary layer between the insulating resin layer and the polymer adhesive layer, the polymer adhesive layer comprising the polymer precursor comprising a functional group that forms an interaction with a plating catalyst or a precursor thereof; and
a polymerizable group as the reactive group capable of forming a bond with an adjacent layer on the first wiring substrate side.

6. The method for producing a multilayer wiring substrate according to claim 1, wherein the process (1) of forming a laminated body comprises transferring a sheet that has been formed by providing the polymer adhesive layer on the insulating resin layer in advance, onto the surface of the first wiring substrate.

7. The method for producing a multilayer wiring substrate according to claim 1, wherein the second metal wiring formed by the first electroless plating treatment is a copper film and a thickness of the formed copper film is from 0.2 μm to 2 μm.

8. The method for producing a multilayer wiring substrate according to claim 4, wherein the process (5) of carrying out a second electroless plating treatment or an electrically conductive paste filling treatment at the formed via portion, to electrically connect the metal wiring on the surface of the first wiring substrate and the second metal wiring that has been formed on the surface of the patterned polymer adhesive layer, is carried out before or after the process (6) of forming a plating resist layer on the surface of the second metal wiring that has been formed on the surface of the patterned polymer adhesive layer and the process (7) of patterning the plating resist layer.

9. The method for producing a multilayer wiring substrate according to claim 1, wherein the polymer precursor comprises a cyano group and a polymerizable group.

10. A multilayer wiring substrate comprising a laminated body comprising an insulating resin layer and a patterned polymer adhesive layer, on a surface of a first wiring substrate comprising a metal wiring thereon, in which the patterned polymer adhesive layer comprises a polymer comprising a cyano group as a functional group that forms an interaction with a plating catalyst or a precursor thereof, wherein the laminated body comprises an adhesion auxiliary layer between the insulating resin layer and the patterned polymer adhesive layer, and the laminated body comprises a via portion which is not covered with the insulating resin layer and the patterned polymer adhesive layer, and a second metal wiring on a surface of the patterned polymer adhesive layer, and a ratio of Ra of the surface of the patterned polymer adhesive layer on the side of the second wiring to Ra of an inner face of the via portion is from 0.05 to 0.50.
